(19) United States
(12) Patent Application Publication
(10) Pub. No.: US 2009/0081590 A1
(43) Pub. Date: Mar. 26, 2009

(54) NEGATIVE RESIST COMPOSITION AND PROCESS FOR FORMING RESIST PATTERNS

(75) Inventor: Hiroshi Shimbori, Kawasaki-shi (JP)

Correspondence Address: KNOBBE MARTENS OLSON & BEAR LLP, 2040 MAIN STREET, FOURTEENTH FLOOR, IRVINE, CA, 92614, US

(73) Assignee: TOKYO OHKA KOGYO CO., LTD., Kawasaki-shi (JP)

(21) Appl. No.: 11/914,123

(22) PCT Filed: Apr. 18, 2006
(86) PCT No.: PCT/JP2006/308130

§ 371 Date: Dec. 15, 2008

(30) Foreign Application Priority Data
May 11, 2005 (JP) 2005-138326
May 11, 2005 (JP) 2005-138327

(51) Int. Cl. G03F 7/004; G03F 7/20

(52) U.S. Cl. 430/287.1; 430/270.1; 430/325

(57) ABSTRACT

A negative resist composition is provided wherein the composition has the sensitivity to g-rays, i-rays, KrF excimer lasers and electron rays, and can be used for mix and match wherein exposure is conducted using at least two exposure light sources selected form g-rays, i-rays, KrF excimer lasers and electron rays. Furthermore, a negative resist composition and a resist pattern forming method are also proposed wherein a resist pattern having excellent high resolution and excellent plating resistance can be formed, and they can be used for manufacturing MEMS. That is, the present invention proposes: a negative resist composition which is used for a process in which at least two exposure light sources selected from g-rays, i-rays, KrF excimer lasers and electron rays are used and comprises an alkali-soluble resin component (A), acid generator component (B), which generates acid due to exposure to g-rays, i-rays, KrF excimer lasers and electron rays, and a crosslinking agent (C); and a negative resist composition which is used for manufacturing MEMS and comprises an alkali-soluble novolak resin (A), an acid generator component (B) which generates an acid due to the exposure of radiation and a crosslinking agent component (C).

### BACKGROUND OF THE INVENTION

1. Technical Field

The present invention relates to a negative resist composition and a process for forming a resist pattern, wherein at least two exposure light sources selected from g-rays, i-rays, KrF excimer lasers and electron rays are used for an exposure step of the composition and a process.

Furthermore, the present invention relates to a negative resist composition and a process for forming a resist pattern, which are suitably used for producing MEMS (Micro Electro Mechanical Systems) sum as a magnetic head.

Priority is claimed on Japanese Patent Application No. 2005-138327, filed May 11, 2005, and Japanese Patent Application No. 2005-138326, filed May 11, 2005, the content of which is incorporated herein by reference.

2. Background Art

The miniaturization processing technique based on lithography techniques has been adopted in the production of semiconductor elements, liquid crystal display elements and the like, and in recent years, further miniaturizing has advanced rapidly according to the advance of the lithography techniques. Typically, shortening of the wavelength of the exposure light has been adopted as a method for the miniaturization. Concretely, ultraviolet radiation such as g-rays and i-rays has been used for conventional methods as the exposure light, but currently, KrF excimer lasers (248 nm) are mainly used for mass production and furthermore KrF excimer lasers (193 nm) are started to be introduced for mass production. Moreover, lithography techniques wherein F₂ excimer lasers (157 nm), EUV (extreme ultraviolet), electron betas (EB) and the like are used as a light source (radiation source) have been also studied.

Resist materials used for the lithographic techniques are required to have sensitivity to the exposure light source. Base resins having coat-forming ability are generally used as resist materials. G-rays and i-rays have been mainly used conventionally as light sources. When these light source are used for exposing a negative composition, for example, many (non-chemically amplification type) negative resist compositions including a combination of an alkali-soluble novolak resin as a base resin and an amino resin such as a melamine resin and a urea resin as a crosslinking agent have been used.

According to the required size miniaturization and the adoption of shorter wavelengths of the exposure light source in recent years, resist materials are further required to achieve further improvements of resolution and sensitivity to the exposure light source. Therefore, after KrF excimer lasers are used for the exposure light source, chemically amplified resist compositions including a base resin and an acid generator which generates acid due to exposure are mainly used as a resist material. For example, as a negative resist, a chemically amplified resist which includes an alkali-soluble resin, an acid generator and a cross-linking agent has been used, and when an acid is generated from the acid generator by exposure at the time of forming the rest pattern, the exposed portions are converted to a alkali-insoluble state.

Furthermore, the kind of base resin used as a resist material is selected due to the use of the shorter wavelength of the exposure light. For example, when KrF excimer lasers are used as a light source, polyhydroxystyrene (PHS) resins are mainly used. Furthermore, when ArF excimer lasers are used as a light source, a resin (acrylic resins) which includes in a main chain thereof a structural unit derived from (meth)acrylic acid is generally used.

Furthermore, as a method for forming a high resolution pattern, study has been conducted from the viewpoint of not only materials but also processes.

For example, a multilayered resist method has been proposed such as a three-layered resist method wherein an organic film, an intermediate film consisting of an inorganic film including silica and a resist film are laminated on a substrate in this order, and a two-layered resist method which is superior to said three-layered resist method from the viewpoint of a smaller number of steps (for example, refer to Patent documents 1 and 2). Such multilayered resist methods may achieve high resolution. However, the multilayered resist method has problems such as cost, lowering of a throughput and deterioration of the yield due to the increase of the number of processes.

Problems regarding throughput are especially important in the lithography process wherein electron rays are used. High resolution may be realized by said lithography process. However, in this method, exposure is usually performed in the vacuum condition by conducting direct exposure or exposure conducted through a desired mask pattern, and therefore, it is necessary to conduct operations for decompression, purging and the like, and takes time compared with the process wherein an excimer laser or the like is used. Furthermore, a long time is required for conducting patterning of a whole substrate when the direct exposure using election rays is conducted.

Accordingly, a method wherein two or more types of light sources are used (hereinafter, described as “mix and match”) is noted in recent years.

In general, a total pattern is formed using a light source such as electron rays required for forming a fine pattern. However, for example, said “mix and match” method uses electron rays for forming a fine pattern and uses other rays such as KrF excimer lasers for forming a rough pattern which does not require high resolution. Since exposure is conducted at once with a mask pattern in the method the time required for forming a rough pattern can be decreased, and it is supposed that a throughput can be increased.

The other hand, MEMS is one of the techniques noted in recent years, MEMS is an advanced small system in which various fine structures (functional elements such as a sensor, and contact terminals such as an electrode, wiring, a vamp and a lead) are integrated on a substrate by a micromachining technique which is a three-dimensional ultra-fine processing technique. MEMS is expected to be developed in various fields such as information telecommunications, automobiles, medical treatment and biotechnology, as various sensors such as a magnetic head of the magnetic recording medium and the like.

The lithography technique is used for the micromachining technique used for manufacturing of the MEMS. For example, a method wherein a micro device such as a magnetic head is formed by using a resist pattern having a specific form is described in a Patent document 3.

Patent document 1: Japanese Unexamined Patent Application, First Publication No. 6-202338

Patent document 2: Japanese Unexamined Patent Application, First Publication No. 8-29987

Patent document 3: Japanese Unexamined Patent Application, First Publication No. 2002-110536

### DISCLOSURE OF INVENTION

### Problems to be Solved by the Invention

As described above, a composition of resist materials is changed in accordance with the kind of an exposure light source used and a general composition does not have sensitivity regarding plural light sources such as three or more kinds of light sources. For example, a non-chemically amplification type resist, which has been used for the exposure to g-rays or i-rays, has sensitivity neither to KrF excimer lasers nor electron rays, and therefore the resist can not be used for “mix and match” wherein these light sources are used. Therefore, the combination of light sources which be used for “mix and match” is restricted.

Accordingly, there is an increasing demand for resist materials which can be used for the “mix and match” even if any of said light sources is used for the resist materials. Especially, resist materials are strongly required which can be used for the “mix and match”, wherein the combination of electron rays which can form a pattern with high resolution and another light source is used, especially wherein the combination of electron rays and widely used g-rays and/or i-rays is used.

The present invention is made in view of the aforementioned circumstances, and the purpose of the present invention is to propose a negative resist composition and a resist pattern formation method using the negative resist composition, wherein the resist composition has the sensitivity to g-rays, i-rays, KrF excimer lasers and electron rays and can be used for the mix and match process wherein the exposure is conducted using at least two exposure light sources selected from g-rays, i-rays, KrF excimer lasers and electron rays.

While the miniaturization degree further increases in MEMS, resist materials are required such that a resist pattern of high resolution can be formed from the resist materials in order to perform the miniaturization processing.

Making the wavelength of an exposure light source short is employed in general as described above as the technique for achieving the miniaturization.

However, there are problems, for example, that the conventional chemically amplified negative resist compositions using a PHS-based resin or the like as a resin component have insufficient resistances required in the production of MEMS, although the resist compositions are reported to form resist pattern with high resolution and high sensitivity.

For example, when MEMS is manufactured, a resist pattern can be formed using resist materials, and then plating can be conducted in the non-resist part of this resist pattern to form a fine metal structural object such as a wiring, a contact terminal or the like. The resist materials are required to have resistance plating resistance) against the plating liquid or the like used for the plating.

However, when the aforementioned conventional chemically amplified negative resist composition is used, there are problems such that the plate separates due to plate thickening or the like which is caused at the plating treatment.

The present invention is provided in view of the aforementioned circumstances, and the purpose of the present invention is to provide a negative resist composition, which can form the resist pattern excellent in plating resistance and ca be used suitably for MEMS, and a resist pattern forming method.

### SUMMARY OF THE INVENTION

As the result of intensive investigation, the inventors of the present invention discovered that the aforementioned problems can be solved by selecting and using a material having specific characteristics as an acid generator, and achieved the present invention.

That is, a first aspect of the present invention is a negative resist composition used for a process in which at least two exposure light sources selected from g-rays, i-rays, KrF excimer lasers and electron rays are used; wherein

the negative resist composition comprises an alkali-soluble resin component (A), acid generator component (B), which generates add due to exposure to g-rays, i-rays, KrF excimer lasers and electron rays, and a crosslinking agent (C).

A second aspect of the present invention is a resist pattern forming method which comprises:

forming a resist film on a substrate using the negative resist composition of the first aspect;

exposing the resist film selectively using at least two of exposure light sources selected from g-rays, i-rays, KrF excimer lasers and electron rays; and

performing alkali development of the exposed resist film to form a resist pattern.

A third aspect of the present invention is a negative resist composition for manufacturing MEMS, which comprises an alkali-soluble novolak resin (A), an acid generator component (B) which generates an acid due to the exposure of radiation and a crosslinking agent component (C).

Moreover, a fourth aspect of the present invention is a resist pattern forming method which comprises: forming a resist film on a substrate using the negative resist composition of the third aspect;

exposing the resist film selectively; and

performing alkali development of the exposed resist film to form a resist pattern.

In the present invention, the radiation of electron rays can be included in examples of the exposure.

### EFFECTS OF THE INVENTION

According to the first and the second aspects of the present invention, it is possible to provide a negative resist composition and a resist patter forming method, wherein the resist composition has the sensitivity to g-rays, i-rays, KrF excimer lasers and electron rays and can be used in a process wherein exposure is conducted using at least two exposure light sources selected from g-rays, i-rays, KrF excimer lasers and electron rays. Due to the use of the negative resist composition and the resist pattern forming method, the “mix and match” can be performed using any of g-rays, i-rays, KrF excimer lasers and electron rays.

According to the third and fourth aspects of the present invention, it is possible to provide a negative resist composition and a resist pattern forming method, wherein a resist pattern with high resolution and excellent in plating resistance can be formed, and therefore they can be used suitably for forming MEMS.

### BRIEF DESCRIPTION OF THE DRAWINGS

FIG. 1 is a view in which a process for forming a resist pattern by the “mix and match” method using i-rays and electron rays is explained.

FIG. 2 is a view in which a process for forming a resist pattern by the “mix and match” method using i-rays and electron rays is explained.

FIG. 3 is a perspective view of a resist pattern formed by the “mix and match” method using i-rays and electron rays.

FIG. 4 is a sectional view of a pattern formed by the “mix and match” method using i-rays and electron rays.

FIG. 5A is a view in which a process for forming a lead part of a magnetic head using a pattern, which is formed by the “mix and match” method using i-rays and electron rays, is explained.

FIG. 5B is a view in which a process for forming a lead part of a magnetic head using a pattern, which is formed by the “mix and match” method using i-rays and electron rays, is explained.

FIG. 5C is a view in which a process for forming a lead part of a magnetic head using a pattern, which is formed by the “mix and match” method using i-rays and electron rays, is explained.

FIG. 6A is a schematic view in which a process for forming a magnetic film pattern using a resist pattern as a mask by ionic etching is explained.

FIG. 6B is a schematic view in which a process for forming a magnetic film pattern using a resist pattern as a mask by ionic etching is explained.

FIG. 6C is a schematic view in which a process for forming a magnetic film pattern using a resist pattern as a mask by ionic etching is explained.

FIG. 6D is a schematic view in which a process for forming a magnetic film pattern using a resist pattern as a mask by ionic etching is explained.

FIG. 6E is a schematic view in which a process for forming a magnetic film pattern using a resist pattern as a mask by ionic etching is explained.

FIG. 7A is a schematic view in which a process for forming a magnetic film pattern using a resist pattern as a forme by the plating method is explained.

FIG. 7B is a schematic view in which a process for forming a magnetic film pattern using a resist pattern as a frame by the plating method is explained.

FIG. 7C is a schematic view in which a process for forming a magnetic film pattern using a resist pattern as a frame by the plating method is explained.

### BRIEF DESCRIPTION OF THE REFERENCE SYMBOLS

11 Substrate
12′ Magnetic film
12 Magnetic film pattern
13 Base pattern
15 Pattern
16 Electrode film
110 Magnetic head (Lead portion)
111 large area pattern
112 Line pattern
113 Resist pattern
21 Substrate
22′ Magnetic film
22 Magnetic film pattern
23′ Base pattern
23 Base film
24′ Resist film
24 Resist pattern
25 Pattern
26 Electrode film
210 Magnetic head (Lead portion)
211 Plating seed layer
212 Resist pattern
213′ Magnetic film
213 Magnetic film pattern

### DETAILED DESCRIPTION OF THE INVENTION

### Negative Resist Composition of the First Aspect of the Present Invention

The negative resist composition of the first aspect of the present invention is a negative resist composition which can be used in a process wherein exposure is conducted using at least two exposure light sources selected from g-rays, i-rays, KrF excimer lasers and electron rays, and the resist composition comprises an alkali-soluble resin component (A) (hereinafter, it may be referred to as a component (A)), an acid generator component (B), which generates an acid due to exposure to g-rays, i-rays, KrF excimer lasers and electron rays (hereinafter, it may be referred to as a component (B)) and a crosslinking agent component (C) (hereinafter, it may be referred to as a component (C)).

Regarding the above negative resist composition, when an acid is generated from the component (B) by exposure, crosslinking between the component (A) and the component (C) occurs due to the action of the acid, and therefore the exposed negative resist composition is changed in total such that the composition has an alkali insolubility. Accordingly, when a resist film consisting of the negative resist composition of the preset invention is exposed selectively in the resist pattern formation or said resist film is further heated after to exposure, alkali solubility of the exposed portions varies to alkali insolubility while unexposed portions maintain their alkali-solubility, and therefore, subsequent alkali development can provide a negative resist pattern.

### (Component (A))

The component (A) may be any compound insofar as it is a component soluble in an alkali developer but changes its alkali solubility to alkali insolubility due to the interaction between the component (C) and the component (A). The component (A) can be optionally selected from known compounds which have been used as alkali-soluble resin components for chemically amplified negative resist compositions.

An alkali-soluble novolak resin (hereinafter, it may be simply referred to as a novolak resin) can be preferably used as the component (A) of the negative resist composition of the first aspect of the present invention, since the novolak resin is excellent in ionic etching resistance such as dry etching resistance, heat resistance, implantation resistance and ion milling, adhesion with a substrate, plating resistance and the like, and can be used for various uses.

The novolak resin usable in the present invention is tot restricted especially; and it is possible to select and use any one optionally selected from conventional novolak resins, which have been proposed as film forming materials usable for a negative resist composition.

Preferable examples thereof include a novolak resin obtained by the condensation reaction of an aromatic hydroxy compound with aldehydes or ketones. Examples of the aromatic hydroxy compound usable for the synthesis of the novolak resin include: phenol; cresols such as m-cresol, p-cresol and o-cresol; xylenols such as 2,3-xylenol, 2,5-xylenol, 3,5-xylenol and 3,4-xylenol; alkylphenols such as m-ethylphenol, p-ethylphenol, o-ethylphenol, 2,3,5-trimethylphenol, 2,3,5-triethylphenol, 4-tert-butylphenol, 3-tert-butylphenol, 2-tert-butylphenol, 2-tert-butyl-4-methylphenol and 2-tert-butyl-5-methylphenol; alkoxyphenols such as p-methoxyphenol, m-methoxyphenol, p-ethoxyphenol, m-ethoxyphenol, p-propoxyphenol and m-propoxyphenol; isopropenylphenols such as o-isopropenylphenol, p-isopropenylphenol, 2-methyl-4-isopropenylphenol and 2-ethyl-4-isopropenylphenol; arylphenols such as phenylphenol; and polyhydroxyphenols such as 4,4′-dihydroxybiphenyl, bisphenol A, resorcinol, hydroquinone and pyrogallol. These aromatic hydroxy compounds may be used singly or in combination of two or more.

Examples of the aldehydes usable for the synthesis of the novolak resin include: formaldehyde, paraformaldehyde, trioxane, acetaldehyde, propionaldehyde, butylaldehyde, trimethylacetaldehyde, acrolein, crotonaldehyde, cyclohexanealdehyde, furfural, farylacrolein, benzaldehyde, terephthalaldehyde, phenylacetaldehyde, a-phenylpropylaldehyde, β-phenylpropylaldehyde, o-hydroxybenzaldehyde, m-hydroxybenzaldehyde, p-hydroxybenzaldehyde, o-methylbenzaldehyde, m-methylbenzaldehyde, p-methylbenzaldehyde, o-chlorobenzaldehyde, m-chlorobenzaldehyde, p-chlorobenzaldehyde and cinnamic acid aldehyde. These aldehydes may be used singly or in combination of two or more.

Among these aldehydes, formaldehyde is preferable in view of availability, and it is particularly preferable to use hydroxybenzaldehydes such as o-hydroxybenzaldehyde, m-hydroxybenzaldehyde and p-hydroxybenzaldehyde in combination with formaldehyde so as to improve heat resistance.

Examples of the ketones usable for the synthesis of the novolak resin include: acetone, methyl ethyl ketone, diethyl ketone and diphenyl ketone. These ketones can be used singly or in combination of two or more. Furthermore aldehydes can be appropriately used in combination with ketones.

The novolak resin can be manufactured from the aromatic hydroxy compound and the aldehydes and/or ketones by a conventionally known condensation method in the presence of an acidic catalyst. As the acidic catalyst for example, hydrochloric acid, sulfuric acid, formic acid, oxalic acid and paratoluenesulfonic acid can be used.

The weight average molecular weight (Mw) of the novolak resin (it is determined using gel permeation chromatography (GPC) based on the polystyrene equivalent), that is, Mw of the component (A) before the protection by acid dissociable, dissolution inhibiting groups, is preferably within a range from 2000 to 50000, more preferably from 3000 to 20000, and still more preferably 4000 to 15000. When the Mw is 2000 or more, the coating ability at the time of applying the negative resist composition dissolved in an organic solvent on a substrate is excellent, and when the Mw is 50000 or less, excellent resolution can be achieved.

In the present invention, it is preferable to use a novolak resin to which processing for separating and removing low molecular weight substances has been carried out. Heat-resistance can be improved furthermore by using such a resin.

Here, examples of the low molecular weight substances described in the present specification include, for example, residual monomers which are other monomers used for synthesis of a novolak resin, such as aromatic hydroxy compounds, aldehydes, ketones and the like, dimers in which two residual monomers are combined and trimers in which three residual monomers are combined (two ring or three ring compounds and the like).

There is no limitation regarding the treatment method for separating the low molecular weight substances. For example, examples of the method include known separation methods such as a method wherein purification is conducted using an ion exchange resin and a method where a good solvent (alcohol or the like) of the ion exchange resin and a poor solvent thereof (water or the like) are used. If the former method is used, it is possible to remove an acid component and a metal component in addition to the low molecular weight substances.

A yield obtained by separating and removing the low molecular weight substances from the novolak resin product as a basis is desirably in the range of 50 to 95% by mass. When the yield is 50% by mass or more, the difference of the dissolution rate between an exposed portion and an unexposed portion is large, and therefore excellent resolution can be achieved. When the yield is 95% by mass or less, effects expected by the separating and removing operations can be obtained sufficiently.

It is preferable that the content of low molecular weight substances having Mw 500 or less be 15% or less based on a GPC chart, and 12% or less is still more preferable. When the content thereof is 15% or less, the effect of improving heat resistance can be obtained, while the effect of controlling the amount of sublimate which is generated at the time of heat-treatment is also obtained.

In the negative resist composition of the first aspect of the present invention, a resin having a structural unit derived from hydroxystyrene (hereinafter, it may be referred to as a polyhydroxystyrene (PHS) resin) is also preferably used as the component (A), A pattern with high resolution can be formed by using such a resin. Furthermore, the miniaturization processing is possible even when a thick film is prepared, and therefore, a pattern having a high aspect ratio can be formed and resistance against dry etching and the like can increase.

Here, the meaning of “hydroxystyrene” can include hydroxystyrene, hydroxystyrene in which a hydrogen atom bonded to carbon atom of the α-position of hydroxy styrene is substituted by another substituent such as a halogen atom, an alkyl group and a halogenated alkyl group or the like and derivatives thereof (preferably, derivatives when the aforementioned substituents are bonded to a benzene ring and the like). The number of hydroxyl groups bonding to a benzene ring of the hydroxystyrene is preferably an integer of 1 to 3, and it is more preferable that it is 1. The number of carbon atoms included in the alkyl group, halogenated alkyl group and the like, in which a hydrogen bonding to a carbon atom of the α-position of the hydroxy styrene is substituted is preferably 1 to 5. Here, said α-position of the hydroxystyrene (carbon atom positioned at a position) means a carbon atom which forms a benzene ring insofar as particular explanations are provided.

“Structural unit derived from hydroxystyrene” means a structural unit derived by cleavage of the ethylenic double bond of the hydroxystyrene.

The ratio of the structural unit derived from hydroxystyrene in the PHS-based resin is preferably 50 to 100% by mole and more preferably 80 to 100% by mole based on the total of all structural units forming the PHS-based resin.

Specifically, examples of the PHS-based resin include polyhydroxystyrene and hydroxystyrene-styrene copolymer and the like.

Examples of the hydroxystyrene-styrene copolymer include copolymers including a structural unit (a1) represented by the following general formula (I) and/or a structural unit (a2) represented by the following general formula (II).

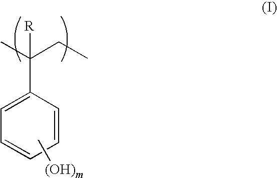

(In the general formula, R represents a hydrogen atom or a methyl group, and m represents an integer of 1 to 3.)

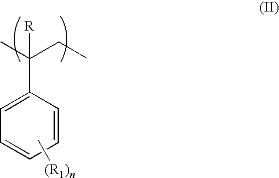

(In the general formula, R represents a hydrogen atom or a methyl group, R₁ represents an alkyl group having 1 to 5 carbon atoms, and n represents an integer of 1 to 3.)

In the structural unit (a1) represented by the general formula (I), R is a hydrogen atom or a methyl group, and preferably is a hydrogen atom.

The m in the unit (a1) is an integer of 1 to 3, and is preferably 1.

The position at which the hydroxyl group is bonded may be o-position, m-position or p-position. From the viewpoint of availability and low cost, such a unit is preferable wherein the m is 1 and a hydroxyl group is positioned at p-position. When m is 2 or 3, any combination of substituent positions can be selected optionally.

In the structural unit (a2) represented by the general formula (I), R is a hydrogen atom or a methyl group, and preferably is a hydrogen atom. The R₁ is preferably a straight chain or branched alkyl group having 1 to 5 carbon atoms, and examples thereof include a methyl group, an ethyl group, a propyl group, an isopropyl group, an n-butyl group, an isobutyl group, a tert-butyl group, a pentyl group, an isopentyl group and a neopentyl group. From an industrial viewpoint, a methyl group and/or an ethyl group are preferable.

The n is 0 or an integer of 1 to 3. Among them, it is preferable that n be 0 or 1, and 0 is particularly preferable from the industrial viewpoint.

When n is 1, the position of R₁ may be o-position, m-position or p-position, and when n is 2 or 3, any combination of substituent positions can be selected optionally.

Moreover, it is possible to use a PHS-based resin wherein alkali solubility thereof is reduced such that 3 to 40% by mole of the hydrogen atom of the hydroxyl group of the polyhydroxystyrene is substituted by an alkali-insoluble group.

Moreover, it is possible to use a PHS-based resin wherein alkali solubility thereof is reduced such that 5 to 30% by mol of the hydrogen atom of the hydroxyl group of the structural unit (at) of the copolymer having the aforementioned structural unit (a1) and unit (a2) is substituted by an alkali-insoluble group.

Said “alkali-insoluble group” is a substituent which reduces alkali-solubility of a substituted alkali-soluble resin, and examples thereof include tertiary alkyloxycarbonyl groups such as tert-butoxycarbonyl group and tert-amyloxycarbonyl group, and a lower alkyl group such as a methyl group, an ethyl group, a n-propyl group, an isopropyl group, a n-butyl and an isobutyl group.

The mass average molecular weight of the PHS-based resin is preferably 1000 to 10000, and is more preferably 2000 to 4000 when KrF excimer lasers and/or electron rays are at least used for the “mix and match” especially.

The content of the component (A) in the negative resist composition of the first aspect of the present invention can be selected in accordance with the resist film thickness which is intended.

### (Component (B))

The component (B) can be any one insofar as it can generate an acid due to the exposure of g-rays, i-rays, KrF excimer lasers and electron rays, and can be optionally selected from compounds which have been proposed as an acid generator for chemically amplified resists.

Here, “it generates acid due to the exposure of g-rays, i-lays, KrF excimer lasers and electron rays” means that an acid can be generated when any one of g-rays, i-rays, KrF excimer lasers and electron rays is exposed as a light source.

Whether or not an acid generator is an acid generator which can generate an acid due to the exposure of g-rays, i-rays, KrF excimer lasers and electron rays can be determined, for example, such that observation for determining the formation of a resist pattern is conducted after a negative resist composition containing an acid generator to be examined and the component (A) is prepared and used for foxing a resist film, and the resist film is exposed selectively using each of g-rays, i-rays, KrF excimer lasers and electron rays, and then developed.

There are various known acid generators proposed for a chemically amplified resist, and examples thereof include; an onium salt-based acid generator such as iodonium salt and sulfonium salt; an oximesulfonate-based acid generator; a diazomethane based acid generator such as an a bisalkyl or bisarylsulfonyldiazomethane acids and poly(bissulfonyl)diazomethanes; a nitrobenzylsulfonate based acid generator; an iminosulfonate based acid generator; and a disulfone based acid generator.

Among them, the oximesulfonate-based acid generator is preferable since the acid generator shows high transparency regarding g-rays, i-rays, KrF excimer lasers, electron rays and the like, and therefore exposure light can permeate within a resist film sufficiently and a resist pattern can be formed with high resolution.

In the present invention, the “oxime sulfonate type acid generator” means a compound which generates acid due to the exposure of radiation, and a compound which contains at least one group represented by the general formula (B-1) shown below, or a compound which is represented by the general formulae (III) or (IV) shown below.

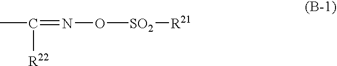

(In the formula (B-1), R²¹ and R²² each independently repents an organic group.)

The above organic groups of R²¹ and R²² are a group including a carbon atom, and can also include atoms other than the carbon atom (such as a hydrogen atom, an oxygen atom, a nitrogen atom, a sulfur atom and a halogen atoms (such as a fluorine atom and a chlorine atom)).

The organic group of R²¹ is preferably a straight chain, branched or cyclic alkyl group or aryl group. These alkyl group and aryl group can also include a substituent. There are no particular restrictions on the substituent, and examples thereof include a fluorine atom, and a straight chain, branched or cyclic alkyl group having 1 to 6 carbon atoms. Here, “include a substituent” means that a portion of, or all of the hydrogen atoms of the alkyl group or aryl group are substituted with a substituent.

The alkyl group preferably contains 1 to 20 con atoms, more preferably 1 to 10 carbon atoms, still more preferably 1 to 8 carbon atoms, especially preferably 1 to 6 carbon atoms and most preferably 1 to 4 carbon atoms.

As the alkyl group, an alkyl group that is partially or completely halogenated (hereafter, it may be referred to as halogenated alkyl groups) is preferred. A partially halogenated alkyl group means an alkyl group in which a portion of the hydrogen atoms thereof have been substituted with a halogen atom(s), whereas a completely halogenated alkyl group means an alkyl group in which all of the hydrogen atoms have been substituted with halogen atoms. Examples of the halogen atom include a fluorine atom, a chlorine atom, a bromine atom or an iodine atom. A fluorine atom is particularly preferable. In other words, the halogenated alkyl group is preferably a fluoroalkyl group.

The aryl group preferably contains 4 to 20 carbon atoms, more preferably 4 to 10 carbon atoms, and most preferably 6 to 10 carbon atoms. Aryl groups that are partially or completely halogenated are preferable. A partially halogenated aryl group means an aryl group in which a portion of the hydrogen atoms have been substituted with a halogen atom(s), whereas a completely halogenated aryl group means an aryl group in which all of the hydrogen atoms are substituted with halogen atoms.

As the group R²¹, an alkyl group having 1 to 4 carbon atoms and containing no substituent, or a fluoroalkyl group having 1 to 4 carbon atoms is preferable in particular.

The organic group of R²² is preferably a straight chain, branched or cyclic alkyl group, an aryl group or a cyano group. Examples of the alkyl group and aryl group for R²² can include the same alkyl groups and aryl groups described above in the examples of R²¹.

As the group R²², a cyano group, an alkyl group having 1 to 8 carbon atoms and containing no substituent and a fluoroalkyl group having 1 to 8 carbon atoms are preferable.

Compounds represented by the general formulae (III) and (IV) shown below (refer to U.S. Pat. No. 6,004,724) can be used preferably as the oxime sulfonate-based acid generators, since they can achieve high acid generation ratio due to the exposure of radiation.

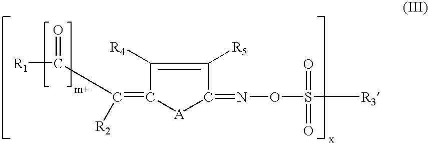

(In the general formula, m′ represents 0 or 1; X represents 1 or 2; R₁ represents CN, a phenoxycarbonyl group or an alkoxycarbonyl group having 2 to 6 carbon atoms when m′ is 0, or a hetero aryl group or a phenyl group which can be substituted with one or more alkyl groups having 1 to 12 carbon atoms; R₂ has the same meaning as in R₁; R³′ represents an alkyl group having 1 to 18 carbon atoms when X represents 1, and an alkylene group having 2 to 12 carbon atoms or a phenylene group when X represents 2; R₄ and R₅ each independently represents a hydrogen atom, a halogen atom or an alkyl group having 1 to 6 carbon atoms; A represents S, O or N(R₆); and R₆ represents an alkyl group having 1 to 4 carbon atoms.)

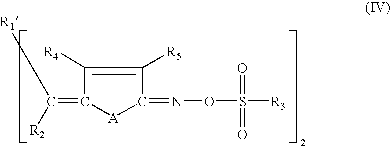

(In the general formula (IV), R₁′ represents an alkylene group having 2 to 12 carbons; R₂, R₄, R₅ and A have the same me ng as in the above formula (III); and R₃ represents an alkyl group having 1 to 18 carbon atoms.)

As the above compound, thiolene containing oxime sulfonate represented by the following general formulae (V) can be preferably used.

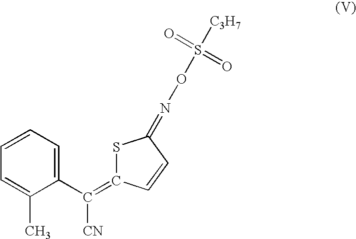

Furthermore, examples of the component (B) also include; a triazine compound (VI) represented by the general formula (VI) (bis(trichloromethyl)triazine), a combination of the triazine compound (VI) and a triazine compound represented by the general formula (VII) (bis(trichloromethyl)triazine) which can be optionally combined (refer to Japanese Patent Application, First Publication No. Hei 6-289614 and Japanese Patent Application and First Publication No. Hei 7-134412), a compound represented by the general formula (VIII) and a compound represented by the general formula (IX).

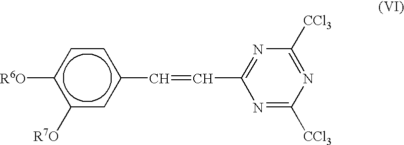

(In the general formula, R⁶ and R⁷ each independently represents an alkyl group having 1 to 3 carbon atoms.)

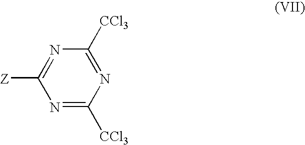

(In the general formula, Z represents a phenyl group having 1 to 4 carbon atoms, a naphthyl group substituted with an alkoxy group having 1 to 4 carbons, a naphthyl group substituted with a carboxy group and an alkoxy group having 1 to 4 carbons, a naphthyl group substituted with an alkoxy group having 1 to 4 carbons and a hydroxy group, a furyl ethenyl group which may be substituted with an alkyl group having 1 to 3 carbon atoms, a phenyl ethenyl group which is substituted with an alkoxy group having 1 to 3 carbon atoms at one or two position each independently, a methylenedioxyphenyl group and a methylenedioxyphenylethenyl group.)

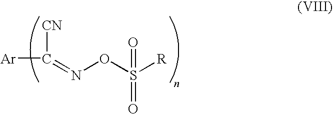

(In the general formula, Ar represents a substituted or unsubstituted phenyl group or naphthyl group; R represents an alkyl group having 1 to 9 carbon atoms; and n represents an integer of 2 or 3.)

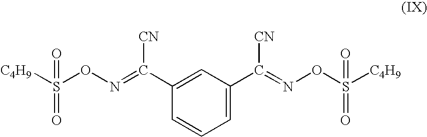

Specific examples of the triazine compound (VI) include; 2-[2-(3,4-dimethoxyphenyl)ethenyl]-4,6-bis(trichloromethyl)-1,3,5-triazine, 2-[2-(3-methoxy-4-ethoxyphenyl)ethenyl]-4,6-bis(trichloromethyl)-1,3,5-triazine, 2-[2-(3-methoxy-4-propoxyphenyl)ethenyl]-4,6-bis(trichloromethyl)-1,3,5-triazine, 2-[2-(3-ethoxy-4-methoxyphenyl)ethenyl]-4,6-bis(trichloromethyl)1,3,5-triazine, 2-[2-(3,4-diethoxyphenyl)ethenyl]-4,6-bis(trichloromethyl)-1,3,5-triazine, 2-[2-(3-ethoxy-4-propoxyphenyl)ethenyl]4,6-bis(trichloromethyl)-1,3,5-triazine, 2-[2-(3-propoxy-4-methoxyphenyl)ethenyl]-4,6-bis(trichloromethyl)-1,3,5-triazine, 2-[2-(3-propoxy-4-ethoxyphenyl)ethenyl]-4,6-bis(trichloromethyl)-1,3,5-triazine, 2-[2-(3,4-dipropoxyphenyl)ethenyl]-4,6-bis(trichloromethyl)-1,3,5-triazine. These triazine compounds may be used singly or in combination of two or more.

Examples of the triazine compound (VII) which is optionally used in combination with the triazine compound (VI) include; 2-(4-methoxyphenyl)4,6-bis(trichloromethyl)-1,3,5-triazine, 2-(4-ethoxyphenyl)-4,6-bis(trichloromethyl)-1,3,5-triazine, 2-(4-propoxyphenyl)-4,6-bis(trichloromethyl)-1,3,5-triazine, 2-(4-butoxyphenyl)-4,6-bis(trichloromethyl)-1,3,5-triazine, 2-(4-methoxynaphthyl)-4,6-bis(trichloromethyl)-1,3,5-triazine, 2-(4-ethoxynaphthyl)-4,6-bis(trichloromethyl)-1,3,5-triazine, 2-(4-propoxynaphthyl)-4,6-bis(trichloromethyl)-1,3,5-triazine, 2-(4-butoxynaphthyl)-4,6-bis(trichloromethyl)-1,3,5-triazine, 2-(4-methoxy-6-carboxynaphthyl)-4,6-bis(trichloromethyl)-1,3,5-triazine, 2-(4-methoxy-6-hydroxynaphthyl)-4,6-bis(trichloromethyl)1,3,5-triazine, 2-[2-(2-furyl)ethenyl]-4,6-bis(trichloromethyl)-1,3,5-triazine, 2-[2-(5-methyl-2-furyl)ethenyl]-4,6-bis(trichloromethyl)-1,3,5-triazine, 2-[2-(5-ethyl-2-furyl)ethenyl]-4,6-bis(trichloromethyl)-1,3,5-triazine, 2-[2-(5-propyl-2-furyl)ethenyl]-4,6-bis(trichloromethyl)-1,3,5-triazine, 2-[2-(3,5-dimethoxyphenyl)ethenyl]-4,6-bis(trichloromethyl)-1,3,5-triazine, 2-[2-(3-methoxy-5-ethoxyphenyl)ethenyl]-4,6-bis(trichloromethyl)-1,3,5-triazine, 2-[2-(3-ethoxy-5-propoxyphenyl)ethenyl]-4,6-bis(trichloromethyl)-1,3,5-triazine, 2-[2-(3-ethoxy-5-methoxyphenyl)ethenyl]-4,6-bis(trichloromethyl)-1,3,5-triazine, 2-[2-(3,5-diethoxyphenyl)ethenyl]-4,6-bis(trichloromethyl)-1,3,5-triazine, 2-[2-(3-ethoxy-5-propoxyphenyl)ethenyl]-4,6-bis(trichloromethyl)-1,3,5-triazine, 2-[2-(3-propoxy-5-methoxyphenyl)ethenyl]-4,6-bis(trichloromethyl)-1,3,5-triazine, 2-[2-(3-propoxy-5-ethoxyphenyl)ethenyl]-4,6-bis(trichloromethyl)-1,3,5-triazine, 2-[2-(3,5-dipropoxyphenyl)ethenyl]-4,6-bis(trichloromethyl)-1,3,5-triazine, 2-(3,4-methylenedioxyphenyl)4,6-bis(trichloromethyl)-1,3,5-triazine and 2-[2-(3,4-methylenedioxyphenyl)ethenyl]-4,6-bis(trichloromethyl)-1,3,5-triazine.

These triazine compounds may be used singly or in combination of two or more.

These compounds may be used singly or in combination of two or more. Among the compounds shown above, the compounds represented by the general formulae (V) and (IX) can be preferably used since a high acid generating ratio can be achieved regarding electron rays exposed.

In the present invention, as the component (B), the aforementioned oxime sulfonate-based acid generator can be used in combination with an onium salt-based acid generator.

Examples of the onium salt-based acid generator include compounds represented by the following general formula (b-1) or (b-2).

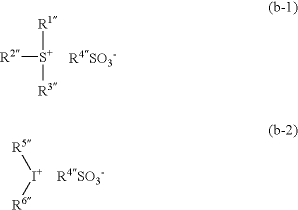

(wherein, R¹″ to R³″ and R⁵″ to R⁶″ each independently represents an aryl group or alkyl group; R⁴″ represents a straight chain, branched or cyclic alkyl group or fluoroalkyl group; and at least one of said R¹″ to R³″ represents an aryl group, and at least one of the R⁵″ to R⁶″ represents an aryl group)

In the formula (b-1), R¹″ to R³″ each independently represents an aryl group or alkyl group. Among R¹″ to R³″, at least one group represents an aryl group. Among R¹″ to R³″, at least two of R¹″ to R₃″ preferably represent aryl groups, and all of R¹″ to R³″ most preferably represent aryl groups.

There are, no partings restrictions on the aryl group of R¹″ to R³″, and examples thereof include aryl groups of 6 to 20 carbon atoms, in which a part of or all of the hydrogen atoms of the aryl groups may be either substituted, or not substitute with an alkyl group, an alkoxy group, a halogen atom and the like. From the viewpoint of enabling low-cost synthesis, an aryl group having 6 to 10 carbon atoms is preferable. Specific examples of the group include a phenyl group and a naphthyl group.

The alkyl group that can be used for substitution of the hydrogen atom of the above aryl group is preferably alkyl groups having 1 to 5 carbon atoms, and most preferably a methyl group, an ethyl group, a propyl group, a n-butyl group and a tert-butyl group.

The alkoxy group that can be used for substitution of the hydrogen atom of the above aryl group is preferably alkoxy groups having 1 to 5 carbon atoms, and a methoxy group or methoxy group are most preferable.

The halogen atom that can be used for substitution of the hydrogen atom of the above aryl groups is preferably a fluorine atom.

There are no particular restrictions on the alkyl groups of R¹ to R³, and examples thereof include straight-chain, branched, or cyclic alkyl groups having 1 to 10 carbon atoms. From the viewpoint of achieving excellent resolution, alkyl groups having 2 to 5 carbon atoms are preferable. Specific examples thereof include a methyl group, an ethyl group, an n-propyl group, an isopropyl group, an a-butyl group, an isobutyl group, an n-pentyl group, a cyclopentyl group, a hexyl group, a cyclohexyl group, a nonyl group and a decanyl group, the terms of achieving superior resolution and enabling low-cost synthesis, a methyl group is the most preferable.

Of the above possibilities, compounds in which R²″ to R¹″ are all phenyl groups are the most preferable.

R⁴″ represents a straight chain, branched, cyclic alkyl group, or a fluorinated alkyl group.

The straight chain alkyl group has preferably 1 to 10 carbon atoms, more preferably 1 to 8 carbon atoms, and most preferably 1 to 4 carbon atoms.

The cyclic alkyl chain is the same with those shown for R¹″ and preferably has 4 to 15 carbon atoms, more preferably 4 to 10 carbon atoms and most preferably 6 to 10 carbon atoms.

The fluorinated alkyl group preferably has 1 to 10 carbon atoms, more preferably 1 to 8 carbon atoms and most preferably 1 to 4 carbon atoms. The fluorination rate of the fluorinated alkyl group (the ratio of the fluorine atom within the alkyl group) is preferably 10 to 100% and more preferably 50 to 100%, and a fluorinated alkyl group in which all of the hydrogen atoms have been substituted with fluorine atoms is particularly preferable since it can generate the strongest acid.

R¹″ is most preferably a straight-chain or cyclic alkyl group, or a fluorenyl group.

In the formula (b-2), R⁵″ to R⁶″ each independently represents an aryl group or an alkyl group. At least one of R⁵″ to R⁶″ represents an aryl group. It is preferable that all of R⁵″ to R⁶″ be aryl groups.

Examples of the aryl groups of the R⁵″ to R⁶″ include the same aryl groups as those described above for the groups R¹″ to R³″.

Examples of the alkyl groups of the groups R⁵″ to R⁶″ include the same alkyl groups as those described above for the groups R¹″ to R³″.

Among them, it is most preferable that all of R⁵″ to R⁶″ be phenyl groups.

Examples of the group R⁴″ in the formula (b-2) include the same groups as those described for the group R⁴″, in the aforementioned formula (b-1).

Specific examples of the onium salt-based acid generators include; trifluoromethane sulfonate or nonafluorobutane sulfonate of phenyliodonium, trifluoromethane sulfonate or nonafluorobutane sulfonate of bis(4-tert-butylphenyl)iodonium, trifluoromethane sulfonate of triphenylsulfonium or its heptafluoropropane sulfonate or its nonafluorobutane sulfonate, trifluoromethane sulfonate of dimethyl(4-hydroxynaphthyl)sulfonium or its heptafluoropropane sulfonate or its nonafluorobutane sulfonate, ad trifluoromethane sulfonate of monophenyldimethylsulfonium or its heptafluoropropane sulfonate or its nonafluorobutane sulfonate, trifluoromethane sulfonate of (4-methylphenyl)diphenylsulfonium or its heptafluoropropane sulfonate or its nonafluorobutane sulfonate, trifluoromethane sulfonate of (4-methoxyphenyl)diphenylsulfonium or its heptafluoropropane sulfonate or its nonafluorobutane sulfonate, trifluoromethane sulfonate of tri(4-tert-butyl)phenylsulfonium or its heptafluoropropane sulfonate or its nonafluorobutane sulfonate, and trifluoromethane sulfonate of diphenyl(1-(methoxy)naphthyl)sulfonium or its heptafluoropropane sulfonate or its nonafluorobutane sulfonate. Moreover, it is possible to use an onium salt wherein the anion portion of the onium salt has been substituted to methane sulfonate, n-propane sulfonate, n-butane sulfonate, or n-octane sulfonate.

Furthermore, compounds in which the anion portion within the above general formulae (b-1) and (b-2) has been substituted with an anion portion represented by the general formula (b-3) or (b-4) shown below (the cation portion is the same, as that shown in (b-1) or (b-2)) can also be used.

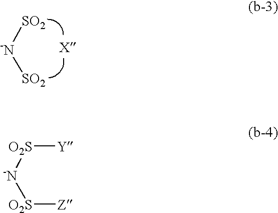

(wherein, X″ represents an alkylene group having 2 to 6 carbon atoms in which at least one hydrogen atom is substituted with a fluorine atom, Y″ and Z″ each independently represents a alkyl group having 1 to 10 carbon atoms in which at least one hydrogen atom is substituted with a fluorine atom.)

X″ is a straight-chain or branched alkylene group in which at least one hydrogen atom is substituted with a fluorine atom, and the number of carbon atoms within the alkylene group is 2 to 6, preferably 3 to 5, and most preferably 3.

Y″ and Z″ each independently represents a straight-chain or branched alkyl group in which at least one hydrogen atom is substituted with a fluorine atom, and the number of carbon atoms within the alkyl group is 1 to 10, preferably 1 to 7, and most preferably 1 to 3.

Within the above ranges of the numbers of carbon atoms, lower numbers of carbon atoms within the alkylene group X″ and/or the alkyl groups Y″ and Z″ are preferable since better solubility within the resist solvent can be achieved.

Furthermore, in the alkylene group X″ and/or the alkyl groups Y″ and Z″, the larger the number of hydrogen atoms substituted with fluorine atoms, the stronger the acid becomes, and the transparency relative to electron beams or high energy light beams of 200 nm or less improves preferably. The fluorine atom ratio within the alkylene group and/or alkyl groups, namely the fluorination ratio, is preferably within a range from 70 to 100%, more preferably from 90 to 100%, and perfluoroalkylene or perfluoroalkyl groups in which all of the hydrogen atoms are substituted with fluorine atoms are most preferable.

These compounds can be used singly or in combination of two or more.

The content of the component (B) is preferably 1 to 30 parts by mass, and most preferably 1 to 20 parts by mass based on the 100 parts by mass of the component (A).

### (Component (C))

The component (C) is not restricted in particular. The component (C) can be optionally selected and used from the known crosslinking agents which have been used for the chemically amplified negative resist composition.

Specific examples of the crosslinking agent include aliphatic cyclic hydrocarbons having either or both of a hydroxy group and a hydroxyalkyl group and oxygen-containing derivatives thereof, such as 2,3-dihydroxy-5-hydroxymethylnorbornane, 2-hydroxy-5,6-bis(hydroxymethyl)norbornane, cyclohexanedimethanol, 3,4,8 (or 9)-trihydroxytricyclodecane, 2-methyl-2-adamantanol, 1,4-dioxane-2,3-diol, and 1,3,5-trihydroxycyclohexane.

Furthermore, examples of the component (C) also include compounds which are obtained by reacting an amino group-containing compound such as melamine, acetoguanamine, benzoguanamine, urea, ethyleneurea, propyleneurea or glycolurile with a lower alcohol and formaldehyde or formaldehyde to substitute a hydrogen atom of the amino group with a hydroxymethyl group or a lower alkoxymethyl group.

Among them, a crosslinking agent obtained by using melamine is referred to as a melamine-based crosslinking agent, a crosslinking agent obtained by using urea is referred to as a urea-based crosslinking agent, a crosslinking agent obtained by using an alkyleneurea such as ethyleneurea or propyleneurea is referred to as an alkyleneurea-based crosslinking agent, and a crosslinking agent obtained by using glycolurile is referred to as a glycolurile-based crosslinking agent.

The component (C) is preferably at least one selected from the melamine-based crosslinking agent, urea-based crosslinking agent, alkyleneurea-based crosslinking agent, and glycolurile-based crosslinking agent; and the melamine-based crosslinking agent is most preferable as the component (C).

Examples of the melamine-based crosslinking agent include compounds obtained by reacting melamine with formaldehyde to substitute a hydrogen atom of the amino group with a hydroxymethyl group, or by reacting melamine with formaldehyde and a lower alcohol to substitute a hydrogen atom of the amino group with a low alkoxy methyl group. Specific examples thereof include hexamethoxymethylmelamine, hexaethoxymethylmelamine, hexapropoxymethylmelamine and hexabutoxybutylmelamine, and among them, hexamethoxymethylmelamine is particularly preferable.

As the urea-based crosslinking agents, examples thereof include a compound obtained by reacting urea with formaldehyde to substitute a hydrogen atom of the amino group with a hydroxymethyl group, and a compound obtained by reacting urea with formaldehyde and a lower alcohol to substitute a hydrogen atom of the amino group with a lower alkoxymethyl group. Specific examples thereof include bismethoxymethylurea, bisethoxymethylurea, bispropoxymethylurea and bisbutoxymethylurea, and among them, bismethoxymethylurea is preferable.

The alkyleneurea-based crosslinking agent includes a compound represented by the general formula (III) shown below.

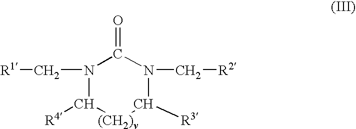

(In the general formula, R¹′ and R²′ each independently represents a hydroxyl group or a lower alkoxy group, R³′ and R⁴′ each independently represents a hydrogen atom, a hydroxyl group or a lower alkoxy group, and v represents an integer of 0, 1, or 2.)

When R¹′ and R²′ are lower alkoxy groups, they are preferably alkoxy groups having 1 to 4 carbon atoms, and may be straight chain or branched. R¹′ and R²′ way be the same or different from each other, and are more preferably the same as each other.

When R³′ and R⁴′ are lower alkoxy groups, they are preferably alkoxy groups having 1 to 4 carbon atoms, and may be straight chain or branched. R³′ and R⁴′ may be the same or different from each other, and are more preferably the same as each other.

The v represents an integer of 0, 1, or 2, and is preferably from 0 or 1.

A compound in which v is 0 (ethyleneurea-based crosslinking agent) and/or a compound in which v is 1 (propyleneurea-based crosslinking agent) are particularly preferably as the alkyleneurea-based crosslinking agent.

The compound represented by the general formula (III) can be obtained by the condensation reaction of alkyleneurea with formaldehyde, or by reacting the product obtained by the above reaction with a lower alcohol.

Specific examples of the alkyleneurea-based crosslinking agent include; an ethyleneurea-based crosslinking agent such as mono- and/or dihydroxymethylated ethyleneurea, mono- and/or dimethoxymethylated ethyleneurea, mono- and/or diethoxymethylated ethyleneurea, mono- and/or dipropoxymethylated ethyleneurea, or mono- and/or dibutoxymethylated ethyleneurea; a propyleneurea-based crosslinking agent such as mono- and/or dihydroxymethylated propyleneurea, mono- and/or dimethoxymethylated propyleneurea, mono- and/or diethoxymethylated propyleneurea, mono- and/or dipropoxymethylated propyleneurea, or mono- and/or dibutoxymethylated propyleneurea; 1,3-di(methoxymethyl)4,5-dihydroxy-2-imidazolidinone; and 1,3-di(methoxymethyl)-4,5-dimethoxy-2-imidazolidinone.

Examples of the glycolurile-based crosslinking agent include a glycolurile derivative in which N-position is substituted with either or both of a hydroxyalkyl group and an alkoxyalkyl group having 1 to 4 carbon atoms. Such a glycolurile derivative can be obtained by the condensation reaction of glycolurile and formaldehyde or reacting the product obtained by the above reaction with a lower alcohol.

Specific examples of the glycolurile-based crosslinking agent include; mono-, di-, tri- and/or tetrahydroxymethylated glycolurile, mono-, di-, tri- and/or tetramethoxymethylated glycolurile, mono-, di-, tri- and/or tetraethoxymethylated glycolurile, mono-, di-, tri- and/or tetrapropoxymethylated glycolurile, and mono-, di-, tri- and/or tetrabutoxymethylated glycolurile.

The component (C) may be used singly or in combination of two or more.

The amount of the component (C) is preferably 3 to 30 parts by mass, more preferably 3 to 15 parts by mass, and most preferably 5 to 15 pares by mass, based on 100 parts by mass of the component (A). When the content of the component (C) is the lower limit or more of the range crosslinking formation can proceed sufficiently, and thus excellent resist pattern can be obtained. Furthermore, when the content of the component (C) is the upper limit or less of the range, the storage stability of a resist coating liquid including the component is good and deterioration of sensitivity due to passage of time can be suppressed.

### (Optional Component)

It is preferable that a nitrogen-containing organic compound (D) (hereinafter, it may be referred to as a component (D)) is added in the negative resist composition of the first aspect of the present invention in order to improve a resist pattern form, post exposure stability of the latent image formed by the pattern-wise exposure of the resist layer and the like.

The component (D) may be any one insofar as it can have compatibility with other components of the negative resist composition, and not restricted in particular. Examples thereof include compounds described in Japanese Patent Application, First Publication No. Hei 9-6001.

Particularly, the addition of a comparatively bulky and specific basic compound (d1) represented by the following general formula (X) can suppress the amount of an acid component which tends to be produced in the resist composition as a by-product with the passage of time, and therefore it can improve the long-term storage stability of the resist composition.

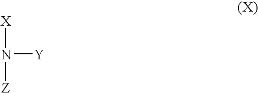

In the general formula (X), at least one (preferably 2 or more, most preferably 3) among X, Y and Z is a group selected from the following (1) to (4); (1) a straight chain or branched alkyl group having 4 or more carbon atoms, (2) a cyclic alkyl group having 3 or more carbon atoms, (3) a phenyl group, and (4) an aralkyl group.

In the case of (1) wherein the alkyl group having 4 or more carbon atoms is used, it is effective to improve the storage stability due to the number of carbon atoms of 4 or more. The number of carbon atoms is more preferably 5 or more, and particularly preferably 8 or more. The upper limit of the number is not specifically restricted, but is preferably 20 or less, and particularly preferably 15 or less, in view of the effect of the storage stability and commercial availability when the number of carbon atoms is more than 20, basic intensity becomes weak and thus the effect of storage stability deteriorates.

The alkyl group of (1) may be straight chain or branched.

Straight chain is particularly preferable, and specific examples thereof include a n-decyl group, a n-octyl group and a n-pentyl group.

In the case of (2) wherein the cyclic alkyl group having 3 or more carbon atoms is used, a cyclic alkyl group having 4 to 8 carbon atoms is preferable in view of commercial availability and excellent effect of improving the storage stability. A cyclohexyl group having 6 carbon atoms is particularly preferable.

The aralkyl group described in the case of (4) is a group wherein a hydrogen atom is removed form a side chain of aromatic hydrocarbon having the side chain, and the aralkyl group can be represented by the general formula: —R′—P (R′ represents an alkylene group and P represents an aryl group). Examples of P of the aryl group include a phenyl group and a naphthyl group, and a phenyl group is preferable. The number of carbon atoms in R′ as the alkylene group may be 1 or more, and is preferably from 1 to 3.

Preferable examples of the aralkyl group of (4) include a benzyl group and a phenylethyl group.

One or two among X, Y and Z may be a group or atom other than the groups of (1) to (4). The group or atom other than the above (1) to (4) is preferably a group or atom selected from: (1′) a straight chain or branched alkyl group having 3 or less carbon atoms and (2′) a hydrogen atom.

The alkyl group having 3 or loss carbon atoms of (1′) may be straight chain or branched alkyl group, A methyl group and an ethyl group are particularly preferable. X, Y and Z may be the same or different from each other. When at least two groups among X, Y and Z are groups selected from the above (1) to (4), these groups are preferably the same as each other in view of stability of effects.

As the basic compound (d1), a compound having a tertiary amine is preferable. Among X, Y and Z, when there is a &up other than (1) to (4), such a group can be preferably selected from the group within (1′).

Specific examples of (1′) include tri-n-decylamine, methyl-di-n-octylamine, tri-n-pentylamine, N,N-dicyclohexylmethylamine and tribenzylamine.

Among these compounds, at least one selected from tri-n-decylamine, methyl-di-n-octylamine and tri-n-pentylamine is preferably used, and tri-n-decylamine is particularly preferable.

As the component (D), pyridine-based compounds can be used. Particularly, 2,6-lutidine is preferably used because excellent post exposure stability of the latent image formed by the pattern-wise exposure of the resist layer can be achieved.

The component (D) can be used singly or in combination of two or more. The content of the component (D) is preferably from 0.01 to 5.0 parts by mass based on 100 parts by weight of the component (A).

A component (E) can be included in the negative resist composition of the first aspect of the present invention optionally in order to prevent a deterioration of sensitivity due to the addition of the component (D), or to improve a resist pattern form and post exposure stability of the latent image formed by the pattern-wise exposure of the resist layer and the like. Examples of the component (E) include an organic carboxylic acid, or a phosphorus oxo acid or derivative thereof. The component (D) and the component (E) can be used in combination, or either one can be used singly.

Examples of suitable organic carboxylic acids include malonic acid, citric acid, malic acid, succinic acid, benzoic acid, and salicylic acid.

Examples of the phosphorus oxo acids or derivatives thereof include; phosphoric acid or derivatives thereof such as esters thereof, such as phosphoric acid, di-n-butyl phosphate and diphenyl phosphate; phosphonic acid or derivatives thereof such as esters thereof, such as phosphonic acid, dimethyl phosphonate, di-n-butyl phosphonate, phenylphosphonic acid, diphenyl phosphonate, and dibenzyl phosphonate; and phosphinic acid or derivatives thereof such as esters thereof, such as phosphinic acid and phenylphosphinic acid. Among them, phosphonic acid is particularly preferable.

The component (E) can be used within a range from 0.01 to 5.0 parts by mass based on 100 parts by mass of the component (A).

The negative resist composition of the first aspect of the present invention preferably includes a storage stabilizer. Due to the addition of the storage stabilizer, it is possible to suppress a decomposition reaction of an organic solvent as described below.

The storage stabilizer is not specifically restricted insofar as it has an action of suppressing the decomposition reaction of the organic solvent, and examples thereof include antioxidants described in Japanese Patent Application, First Publication No. Sho 58-194834. As the antioxidant, phenolic compounds and amine compounds are known. Among these compounds, phenolic compounds are preferable, and 2,6-di(tert-butyl)-p-cresol and derivatives thereof are particularly effective to prevent deterioration of ester solvents and ketone solvents and also are excellent in view of availability, low cost and excellent storage stability effect. Propylene glycol monoalkyl ether acetate and 2-heptanone are particularly excellent in deterioration preventing effect.

The negative resist composition of the first aspect of the present invention preferably includes dye.

The dye described in the present invention is a substance which can adsorb at least one kind emitted from the light source used for “mix and match” and selected from g-rays, i-rays, and KrF excimer lasers. It is possible to control the sensitivity regarding g-rays, i-rays or KrF excimer lasers due to the addition of such a dye, and therefore it is possible to control a balance between the sensitivity to the above rays and sensitivity to another one or more light sources (for example, electron rays). Furthermore, the influence of the standing wave of g-rays, i-rays, or KrF excimer lasers can be decreased, and therefore a decrease of line edge roughness (LER), an improvement of an inplane pattern size uniformity, and an improvement of focus depth and the like can be achieved.

Other miscible additives can also be added to the negative resist composition of the first aspect of the present invention. Examples thereof include additive resins for improving the performance of the resist film, surfactants for improving the coating properties, dissolution inhibitors, plasticizers, colorants, halation prevention agents and the like.

The negative resist composition of the present invention can be used by dissolving materials in an organic solvent.

The organic solvent may be any one insofar as it can dissolve each component used and generate a uniform solution. Examples thereof include known solvents which have been used as a solvent for conventional chemically amplified resists, and one of or two or more solvents selected from them can be used.

Examples of the organic solvent include; lactones such as γ-butyrolactone; ketones such as γ-butyrolactone, acetone, methyl ethyl ketone, cyclohexanone, methyl isoamyl ketone and 2-heptanone; polyhydric alcohols and derivatives thereof, such as ethylene glycol, ethylene glycol monoacetate, diethylene glycol diethylene glycol monoacetate, propylene glycol, propylene glycol monoacetate, dipropylene glycol, and monomethyl ether, monoethyl ether, monopropyl ether, monobutyl ether and monophenyl ether of propylene glycol monomethyletheracetate, dipropylene glycol and dipropylene glycol monoacetate, cyclic ethers such as dioxane; and esters such as methyl lactate, ethyl lactate, methyl acetate, ethyl acetate, butyl acetate, methyl pyruvate, ethyl pyruvate, methyl methoxypropionate and ethyl ethoxypropionate.

These organic solvents may be used singly or in combination of two or more.

In the present invention, a mixed solvent containing propylene glycol monomethyl ether (PGME) and a polar solvent are preferably used. The mixing ratio (mass ratio) can be determined optionally in accordance with factors such as the co-solubility of the PGMEA and polar solvent, and the ratio is preferably from 1:9 to 9:1, and more preferably from 2:8 to 8:2.

There are no particular limitations on the amount of the organic solvent. The amount can be optionally selected in accordance with the coating film thickness required so that a concentration that enables favorable application of the solution to a substrate or the like is provided. The amount of organic solvent is generally set so that the solid content concentration of the resist composition falls within a range from 2 to 60% by mass, preferably from 5 to 50% by mass, and still more preferably from 5 to 40% by mass.

Although some of the organic solvents may decompose with the passage of time to generate acid as a by-product, said decomposition reaction can be inhibited under the existence of the component (D) or the storage stabilizer. Among the organic solvents described above, such an effect is remarkably observed in ester solvents such as PGMEA and ester solvents wherein examples thereof include esters such as butyl acetate. Therefore, ester solvents can be desirably used as an organic solvent under the existence of the (D) component and/or a storage stabilizer, and PGMEA is suitably used in particular.

The negative resist composition of the first aspect of the present invention described above can be used for the process wherein exposure is conducted using at least two exposure light sources selected from g-rays, i-rays, KrF excimer lasers and electron rays.

Since the negative resist composition of the first aspect of the present invention has sensitivity to any of g-rays, i-rays, KrF excimer lasers and electron rays, any of g-rays, i-rays, KrF excimer lasers and electron rays can be used as an exposure light source.

In the present invention, it is particularly preferable that at least electron rays are used as one of the exposure light sources since a fine pattern can be formed. That is, it is preferable that electron rays be used for exposure in combination with at least one selected from g-rays, x-rays, and KrF excimer lasers in the aforementioned process. In such a process, electron rays are used for forming a fine pattern, for example, a fine pattern having a size of 200 nm or less, and g-rays, i-rays, and/or KrF excimer lasers are used for forming a rougher pattern, for example, a pattern having a size exceeding 200 nm. Thus, for example, a throughput can be improved greatly as compared with the case wherein only electron rays are used.

Furthermore, it is preferable to use g-rays and/or i-says from the viewpoint of cost or the like since the exposure devices thereof have favorable prices and cost can be reduced. That is, in the process, it is preferable that the combination of electron rays and g-rays and/or i-rays be used for exposure.

Especially, when two exposure light sources are used as exposure light sources, it is preferable that i-rays and electron rays be used in combination.

The negative resist composition of the first aspect of the present invention can be suitably used for the resist pattern forming method of the second aspect of the present invention, which includes a step of exposing a composition using at least two exposure light sources selected from g-rays, i-rays, KrF excimer lasers and electron rays.

### (Resist Pattern Forming Method of the Second Aspect)

The resist pattern forming method of the second aspect of the present invention include the steps of; forming a resist film on a substrate using the negative resist composition of the first aspect of the present invention; exposing selectively the resist film using at least two exposure light sources selected from g-rays, i-rays, KrF excimer lasers and electron rays; and conducting alkali-development of the resist film to form a resist pattern.

For example, the resist pattern forming method of the second aspect of the present invention be carried out as follows.

That is, at first, the negative resist composition of the first aspect of the present invention is applied with a spinner or the like on a substrate such as a silicone wafer, and then prebaking is conducted at the temperature condition of 60 to 180° C. for 10 to 600 seconds, preferably 60 to 90 seconds, to form a resist film. The thickness of the resist film is not restricted. It is preferable that the thickness of the resist film be from 100 nm to 10 μm, and more preferably 200 nm to 5 μm.

The resist film is exposed selectively using at least one selected from g-rays, i-rays, KrF excimer lasers and electron rays (tie first exposure light source) via a desired mask pattern or without using a mask pattern. That is, exposure is conducted either by exposing through a mask pattern or by patterning via direct irradiation with an electron beam without using a mask pattern.

Next the exposed resist film is further exposed selectively using an exposure light source (the second exposure light source) which is selected from g-rays, i-rays, KrF excimer lasers and electron rays but is different from the first exposure light source, through a desired mask pattern or without using a mask pattern.

After the selective exposure, heat treatment (post exposure baking (PEB)) is conducted at the temperature condition of 80 to 150° C., for 40 to 120 seconds, preferably for 60 to 90 seconds. Then, the resist film is developed using an alkali developer such as an aqueous tetramethylammonium hydroxide (TMAH) solution having a concentration of 0.05 to 10% by mass to form a resist pattern.

In addition, an organic or inorganic antireflection film can be formed between the substrate and the coating of the resist composition.

The combination of the first exposure light source and the second exposure light source is not restricted in particular, and it is possible to select from g-rays, i-rays, KrF excimer lasers and electron rays optionally.

In the present invention, the combination of electron rays and at least one selected from g-rays, i-rays and KrF excimer lasers is preferable as described above, and the combination of electron rays and g-rays and/or i-rays is more preferable, and the combination of electron rays and i-rays is most preferable.

The resist pattern formed in this way can be used for, for example, etching wherein said resist pattern is used as a mask, plating wherein said resist pattern is used as a frame and the like. Accordingly, the resist pattern an be used for manufacture of MEMS (micro electro mechanical systems) or the like, wherein such processes are conducted.

### (Negative Resist Composition of the Third Aspect)

The negative resist composition of the third aspect of the present invention includes an alkali-soluble novolak resin (A) (hereinafter, it may be referred to as a component (A)), an acid generator component (B) which generates an acid due to the exposure of radiation (hereinafter it may be referred to as a component (B)) and a crosslinking agent component (C) (hereinafter, it may be referred to as a component (C)).

### (Component (A))

In the negative resist composition of the third aspect of the present invention, the component (A) is an alkali-soluble novolak resin.

The component (A) is not restricted in particular, and can be optionally selected from general compounds which have been proposed for negative resist compositions as usable materials for forming a film. Suitable examples thereof include a novolak resin obtained by condensing an aromatic hydroxy compound with aldehydes and/or ketones.

The synthetic raw materials, a synthetic method, characteristics, removal of a low molecular substances of the novolak resin and a method for removing the low molecular object from the novolak resin, and the desired content of the novolak resin after the removal of the low molecular substances are the same as those described in the first aspect of the present invention.

### (Component (B))

The acid generator component (B) can be any one insofar as it generates acid due to the exposure of radiation, and it is possible to appropriately select compounds which generate acid due to exposure of radiation from compounds which have been proposed as an acid generator for a chemically amplified photoresist.

As the acid generator, there are various known acid generators, for example, an onium salt-based acid generator such as iodonium salt or sulfonium salt; an oximesulfonate-based acid generator; a diazomethane-based acid generator such as bisalkyl or bisarylsulfonyldiazomethanes or poly(bissulfonyl)diazomethanes; a nitrobenzylsulfonate-based acid generator; an iminosulfonate-based acid generator; and a disulfone-based acid generator.

Among them, an oxime sulfonate-based acid generator is preferable since the acid generator can provide an excellent effect for the third and fourth aspects of the present invention.

Here, an oxime sulfonate based acid generator is a compound which generates in acid due to the exposure of radiation, and also is a compound including at least one group represented by the general formula (B-1), or a compound represented by the general formula (III) or (IV).

Regarding the oxime sulfonate-based acid generator, triazine compounds represented by the general formulae (VI), (VII), (VII) and (IX), and onium type acid generator, those described in the first aspect of the present invention can be applicable.

The content of the component (B) is preferably 1 to 30 parts by mass, and more preferably 1 to 20 parts by mass, based on 100 pas by mass of the component (A), “component (C)”

The component (C) is not restricted in particular, and can be optionally selected and used among known crosslinking agents which have been used for chemically amplified negative resist compositions.

Specific examples thereof include; aliphatic cyclic hydrocarbons having either or both of a hydroxy group and a hydroxy alkyl group such as 2,3-dihydroxy-5-hydroxymethylnorbornane, 2-hydroxy-5,6-bis(hydroxymethyl)norbornane, cyclohexanedimethanol, 3,4,8 (or 9)-trihydroxytricyclodecane, 2-methyl-2-adamantanol, 1,4-dioxane-2,3-diol, and 1,3,5-trihydroxycyclohexane, or oxygen-containing derivative thereof.

The component (C) can be the same with those described in the first aspect of the present invention.

### (Optional Component)

In the negative resist composition of the third aspect of the present invention, it is preferable to include a nitrogen-containing organic compound (D) (hereinafter, it may be referred to as a component (D)) in order to improve resist pattern form, post exposure stability of the latent image formed by the pattern-wise exposure of the resist layer and the like.

The component (D) may be any one insofar as it has the compatibility with other components of the negative resist composition, and is not restricted in particular. For example, compounds described in the Japanese Unexamined Patent Application, First Publication, No. 9-6001 can be cited as an example.

Particularly, by adding a specific basic compound (d1) represented by the general formula (X), which is a comparatively bulky compound, it is possible to obtain effects for inhibiting the increase of the amount of an acid component which tends to be produced as a by-product in the negative resist composition with the passage of time, and it is possible to improve the long-term storage stability of the resist composition.

The component (D) can be the same as those described in the first aspect of the present invention.

Moreover, the negative resist composition of the third aspect of the present invention can include, as an optional component, organic carboxylic acid, phosphorus oxo acid or derivative thereof (E) (hereinafter, they may be referred to as a component (E)) for the purpose of improving resist pattern form and post exposure stability of the latent image formed by the pattern-wise exposure of the resist layer and preventing deterioration of sensitivity which may be caused due to the addition of the component (D) and the like. Both of the component (D) and the component (E) can be used in combination, and it is also possible to use either one singly.

The component (E) of the third aspect of the present invention can be the same as those described in the first aspect of the present invention.

It is preferable that a storage stabilizer is added to the negative resist composition of the third aspect of the present invention since the decomposition reaction of the organic solvent can be inhibited.

The preservation stabilizer of the third asp of the present invention can be the same as those described in the first aspect of the present invention.

The negative resist composition of the third aspect of the present invention can further include optional additives having miscibility such as additional resins for improving performances of the resist film, surfactants for improving coatability, dissolution inhibitors, plasticizers, colorants and antihalation agents if necessary.

The negative resist composition of the third aspect of the present invention can be produced by dissolving materials thereof in an organic solvent.

The organic solvent used in a the third aspect of the present invention can be the same as those described in the first aspect of the present invention.

The negative resist composition of the third aspect of the present invention described above can be used in order to produce MEMS.

As described above, MEMS is an advanced small system in which various fine structural objects (conductive structural objects such as a wiring and a connecting terminal, functional elements such as a sensor, and the like) are integrated on the substrate with a micro-machining technique.

Specific examples thereof include a magnetic head of a magnetic recording medium, a perpendicular magnetic head, and MRAM (magnetic random access memory: nonvolatile memory, which uses a GMR (giant magneto resistive) film and/or a TMR (tunnel magneto resistive) film for a memory element).

When the MEMS is manufactured, a process for forming a conductive structure such as a wiring is performed in addition to a lithography process. Therefore, the negative resist composition of the present invention which can form a resist pattern with excellent plating resistance is suitable for forming MEMS.

Furthermore, the negative resist composition of the present invention has good sensitivity to electron rays. Therefore, in accordance with the advance of the miniaturization of MEMS, the negative resist composition of the present invention can be preferably used in particular for manufacturing MEMS wherein electron rays are used, since a pattern having very high resolution can be formed using the negative resist composition by conducting the lithography using electron rays.

In manufacturing of MEMS, various processes other than the plating process are conducted such as dry etching, ionic etching such as an ion milling or an ion-implantation (hereinafter, it may be referred to as implant) wherein an ionization of impurity such as phosphorus or boron is conducted in a vacuum and the ionized impurity is introduced at the accelerated state in a high electric field into the surface of a substrate. For example, ionic etching of a magnetic film is conducted using a resist pattern as a mask when a lead part of a magnetic head is manufactured. In these processes, the resist pattern may be heated in many cases. The negative resist composition of the present invention includes a novolak resin as the component (A), and therefore the composition is excellent in dry etching resistance, inplant resistance, ionic etching resistance, adhesion to a substrate, heat resistance and the like, and the composition can be suitably used for manufacturing MEMS from these points.

The process for forming a conductive structure on a substrate using a plating method can be performed such that a resist film is formed on an upper surface of a substrate, then a resist pattern is formed as described above, and subsequently, conductor is embedded by the plating method at the portion from which resist is removed (non resist portion), and finally the resist pattern around the conductor is removed.

Examples of the conductive structure formed by the plating method include contact terminals such as a vamps a lead, a metal post and a solder ball, wiring and re-wiring. Furthermore, examples of the conductors include gold, copper, nickel, solder and the like.

The method for plating is not restricted in particular, and the various well-known plating methods can be used.

### (Resist Pattern Forming Method of the Fourth Aspect of the Present Invention)

The resist pattern forming method of the fourth aspect of the present invention comprises the steps of, forming a resist film on a substrate using the negative resist composition of the third aspect of the present invention, exposing the resist film selectively, and conducting alkali-development of the resist film to form a resist pattern.

The resist pattern forming method of the fourth aspect of the present invention can be conducted as follows.

At first, the negative resist composition of the present invention is applied on the surface of a substrate such as a silicon wafer using a spinner or the like, and prebaking is performed under the temperature condition of 60 to 180° C. for 10 to 600 seconds, more preferably 60 to 90 seconds, to form a resist film. The thickness of the resist film is not restricted in particular, and the thickness of the resist film is preferably 100 nm to 10 μm, and more preferably 200 nm to 5 μm.

Next, the resist film is exposed through a desired mask pattern or without using a mask pattern to radiation such as electron rays. That is, drawing is conducted such that exposure is conducted using electron rays via a mask pattern, or exposure is conducted directly without using a mask pattern. Then, a heat treatment (post exposure baking (PEB)) is performed at the temperature condition of 80 to 150° C. for 40 to 120 seconds, and preferably for 60 to 90 seconds. Subsequently, developing is performed using an alkali developing solution such as an aqueous solution of tetramethylammonium hydroxide (TMAH) with a concentration of, for example, 1 to 10% by mass to form a resist pattern.

An organic or inorganic anti-reflective film may be provided between the substrate and the applied layer of the resist composition.

There are no particular limitations on the wavelength used for the exposure, and ultraviolet rays such as g-rays and i-rays, ArF excimer lasers, KrF excimer lasers, F2 excimer lasers, EUV (extreme ultraviolet), VUV (vacuum ultraviolet), electron beams, X-rays, soft X-ray radiation can be used. The negative resist composition of the present invention can use g-rays, i-rays, KrF excimer lasers, and electron rays preferably, and electron rays are particularly preferable.

The resist pattern forming method described above is suitably used for the manufacture process of MEMS as described below.

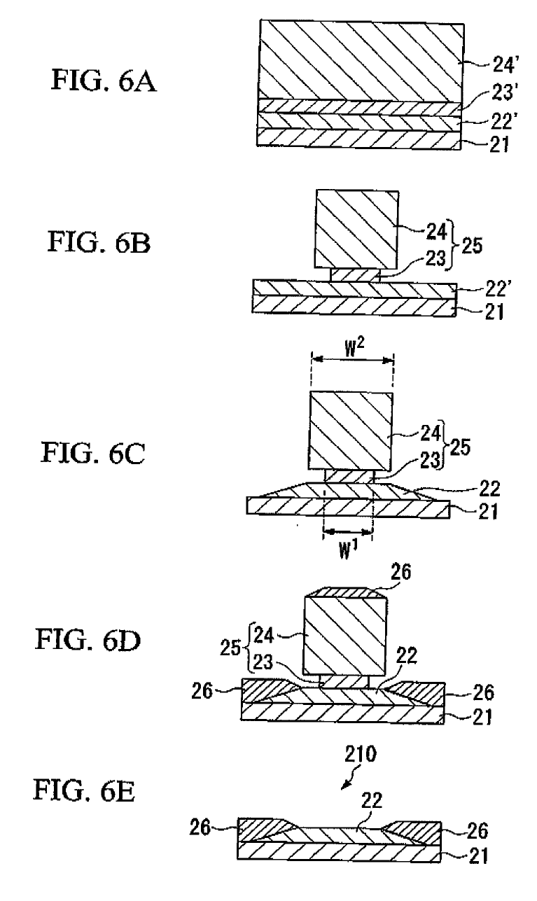

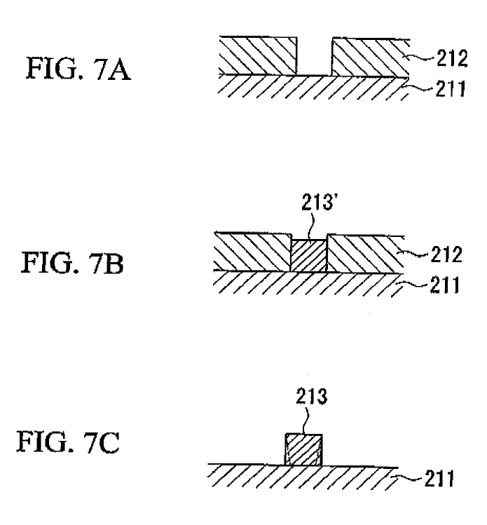

Hereinafter, one example of the manufacturing process of MEMS of the present invention is explained using FIGS. 6A to 6E and FIGS. 7A to 7C.

FIGS. 6A to 6E are schematic views (sectional side view) which show each step for manufacturing a lead portion (read-out head portion) of a magnetic head of a magnetic recording medium.

As shown in FIG. 6A, a magnetic film 22′ is laminated on a substrate 21, and then a base film 23′ which is soluble in an alkali-developer and a resist film 24A′ are further laminated in this order.

Then, exposure is conducted selectively on the resist film 24′ via a mask pattern by using g-rays, i-rays, KrF excimer lasers and/or electron rays and the like. Subsequently, alkali development is conducted to remove the non-exposed portion of the resist film 24′, and a resist pattern 24 is obtained. The portion of the base film 23′, which exists under the resist film 24′ removed by the development, is also removed by the alkali-developer if the base film 23′ is soluble in the alkali developer, and therefore a base film pattern is formed. In general, the base film 23′ has high alkali-solubility as compared with the resist film 24′, and the width W¹ of the base film 23′ tends to be narrower than the width W² of the resist pattern 24. Due to the difference of the dissolution rate, a pattern 25 formed wherein the cross-section thereof is paddle-shaped form, which includes the base pattern 23 having the narrow width and the resist pattern 24 having the width larger than said base pattern, as shown in FIG. 6B.

When said base film 23′ is an alkali-insoluble film, by conducting over-etching using the resist pattern 24 as a mask, the pattern 25, wherein the cross-section of the pattern 25 has paddle-shaped form including the base pattern 23 having the narrow width and the resist pattern 24 having the wider width than said base pattern, is formed as shown in FIG. 6B.

Then, the magnetic film 22′ around the pattern 25 is etched as shown in FIG. 6C by conducting ionic etching using the pattern 25 as a mask, and the magnetic pattern 22 is formed under the pattern 25 and around it. As the ion etching, ion milling is used in many cases.

Furthermore, by conducting sputtering, an electrode film 6 is formed on the substrate 21 around the magnetic film pattern 22 and on the pattern 25 as shown in FIG. 6D.

Finally, the pattern 25 is removed (lift-off) by removing the resist pattern 24 by dissolving the base pattern 23 using an alkali developer and the like. As shown in FIG. 6E, a magnetic head 210 which contains a substrate 21, a magnetic film pattern 22 having the predetermined width formed on the substrate, and an electrode film 26 formed around the pattern can be obtained due to the lift-off of the pattern 25.

Hereafter, a process shown in FIGS. 6A to 6E is explained in detail.

### (Forming Process of a Magnetic Film 22′)

As shown in FIG. 6A, a magnetic film 22′ is formed on a substrate 21 such as a silicone wafer with sputtering equipment.

The substrate is not restricted in particular, and conventionally known substrates can be used and examples thereof include substrates for electronic components. Examples of materials of the substrate include metals such as copper, chromium, iron and aluminum, and glass substrate and silicon wafer. As the magnetic material usable for the magnetic film, 22′ magnetic materials including an atom such as Ni, Co, Cr, Pt and the like can be used.

### (Forming Process of a Base Film 23)

Next, a resist composition or a resin solution used for forming a base film is coated on said magnetic film 22′ using a spinner or the like, and baking treatment is performed for 30 to 300 seconds, preferably 60 to 180 seconds, and preferably under the heating condition of 200 to 300° C., to form the base film 23′.

The base film is an organic film insoluble in an alkali developer which is used after exposure, and is used for the conventional dry etching methods.

Due to the use of such a base film 23′, as described below, only a resist film 24′ is exposed and alkali-developed by the conventional photolithography to form the resist pattern 24, and subsequently, dry etching is performed for the base film 23′ using the resist pattern 24 as a mask to transfer the resist pattern 24 to the base film, and therefore the base pattern 23 of the base film 23′ is obtained.

Materials used for forming the base film 23′ are not necessarily required to have photosensitivity unlike the resist film 24′, and it is possible to use resists and resins which are generally used as base materials for manufacturing a semiconductor device or a liquid crystal display element.

Moreover, it is preferable that the base film 23′ be made of a material which can be etched by oxygen plasma, since the resist pattern 24 is required to be transferred to the base film 23′.

As such a material used for the base film 23′, a material containing, as a main component, at least one selected from the group consisting of a novolak resin, an acrylic resin and a soluble polyimide is preferably used. The reason is that, when such a material is used, etching with oxygen plasma is easily conducted, and excellent resistance to a fluorocarbon-based gas used for etching of a substrate such as a silicon substrate and/or resistance to a dry etching such as ionic etching wherein examples thereof include as ion milling or the like adopted in etching for a substrate or a magnetic film in the post-process can be achieved.

As the novolak resin, novolak resins which are conventionally used for resist compositions can be used, and resists including a novolak resin used for i-rays and g-rays can be also used. For example, examples thereof include those novolak resins described above in the explanation for the component (A).

As the acrylic resin, acrylic resins typically used in positive resist compositions can be used, and examples thereof include acrylic resins containing structural units derived from a polymerizable compound having an other linkage, and structural units derived from a polymerizable compound containing a carboxyl group.

Examples of the polymerizable compound having an ether linkage include; (meth)acrylate derivatives containing an ether linkage and an ester linkage such as 2-methoxyethyl (meth)acrylate, methoxytriethylene glycol (meth)acrylate, 3-methoxybutyl (meth)acrylate, ethylcarbitol (meth)acrylate, phenoxypolyethylene glycol (meth)acrylate, methoxypolypropylene glycol (meth)acrylate, and tetrahydrofurfuryl (meth)acrylate. These compounds can be used singly or in combinations of two or more.

Here, “(meth)acrylate” can mean one of or both of acrylate and methacrylate.

Examples of the polymerizable compound containing a carboxyl group include; monocarboxylic acids such as acrylic acid, methacrylic acid and crotonic acid; dicarboxylic aids such as maleic acid, fumaric acid and itaconic acid; and compounds containing a carboxyl group and an ester linkage such as 2-methacryloyloxyethylsuccinic acid, 2-methacyloyloxyethylmaleic acid, 2-methacryloyloxyethylphthalic acid and 2-methacryloyloxyethylhexahydrophthalic acid. Among them, acrylic acid and methacrylic acid are preferable. These compounds can be used singly or in combinations of two or more.

The soluble polyimide refers to polyimides which can be converted to liquid form in the organic solvents described above.

Among them, the novolak resins and acrylic resin, which have an alicyclic part or an aromatic ring at the side chain thereof are preferably used, since they are not expensive and can be used for multipurpose, and are excellent in resistance to dry etching conducted in the post-process.

### (Forming Process of the Resist Film 24′)

Subsequently, a solution of the negative resist composition is applied to the surface of the base layer film 23′ using a spinner or the like, and then is prebaked (PAB (post applied bake) treatment) to form a resist film 24′. In this way, a laminate is obtained wherein the base film 23′ and the resist film 24′ which is formed from the negative resist composition of the present invention are laminated in this order on the magnetic film 22 existing on the substrate 21.

The prebake conditions vary depending on the factors such as the kinds of each component within the resist composition, the respective blend ratios, the thickness of the applied film and the like. The prebake can be generally conducted under the conditions of 70 to 150° C., and preferably from 80 to 140° C., for a period of 0.5 to 60 minutes.

In addition, an organic or an inorganic antireflection film may be provided between the base film 23′ and the resist film 24′.

The total thickness of the base film 24′ and the resist film 24′ is preferably 15 μm or less, and more preferably 5 μm or less, in view of achieving excellent balance between a throughput, which takes into consideration time required for etching of the base film 23′, and aimed aspect ratio. The lower limit is not restricted in particular, and it can be 0.07 μm or more, preferably 0.1 μm or more, and more preferably 0.35 μm or more.

The thickness of the base film 23′ is preferably from 20 to 10000 nm, more preferably from 30 to 5000 nm, and still more preferably from 30 to 3000 nm. By adjusting the thickness of the base film 23′ within the above range, it is possible to achieve effects such that a resist pattern having a high aspect ratio can be formed and sufficient etching resistance can be secured when the substrate is etched.

The thickness of the resist film 24′ is preferably frown 50 to 1000 nm, more preferably from 100 nm to 800 nm, and still more preferably from 100 to 500 nm. By adjusting the thickness of the resist film 24′ within the above range, it is possible to achieve effects such that a resist pattern 24 can be formed with high resolution and sufficient etching resistance to an alkali developer and ionic etching can be obtained.

In the resist laminate wherein a resist pattern is formed, it is preferable that a pattern having a high aspect ratio be formed without causing pattern collapse. When the resulting pattern has a higher aspect ratio, a finer pattern can be formed on a substrate described below with higher accuracy.

The aspect ratio described in the present invention refers to a ratio of the height y of the base pattern 23 to the pattern width x of the resist pattern, (y/x). The pattern width x of the resist pattern is the same as the width of the base pattern 23 after transferring to the base pattern 23.

The pattern width described in the present invention refers to the width of the line (unremoved portion) when the resist pattern is a line-shaped pattern such as line-and-space pattern or isolated line pattern.

When the resist pattern is a hole pattern, the pattern width refers to an inner diameter of a hole (cavity) formed.

When the resist pattern is a cylindrical dot pattern, the pattern width refers to a diameter thereof. Any of these pattern widths is the width of the lower portion of the pattern.

### (Resist Pattern Forming Process of the Fourth Aspect)

Subsequently, as explained in the aforementioned resist pattern forming method of the fourth aspect, the resist film 24′ is exposed selectively to electron rays through a desired mask pattern or through no mask pattern using electron ray drawing equipment or the like, and then, the film is developed subsequent to PEB treatment, and as a result, the resist pattern 24 as shown in FIG. 6B is obtained by developing the predetermined portion (exposed portion) of the resist film 24′.

### (Over-Etching Process of the Fourth Aspect)

Using the resulting resist pattern 24 as a mask pattern, dry etching of the base film 23′ is conducted to form a base pattern 23 on a base film 23′.

At this time, when over-etching of the base film 23′ is conducted, the base film 23′ located under the resist pattern 24 is also removed, and only the portion of the base film 23′ existing in the vicinity of the center of the resist pattern 24 remains. Consequently, a paddle-shaped pattern 25 having a base patter 23 having a small width W¹ of the base film 23′ and a resist pattern 24 having a larger width W₂ of the resist film 24′ can be obtained as shown in FIG. 6B.

As the dry etching method, conventionally know methods can be used. Examples thereof include chemical etching methods such as downflow etching and chemical dry etching; physical etching methods such as sputter etching and ion beam etching; and chemical and physical etching methods such as RIE (reactive ion etching).

The most popular dry etching method is a parallel-plate RIE method. In this method, a resist laminate is placed in a chamber of RIE equipment and a required etching gas is introduced. When a high frequency voltage is applied to a holder of the resist laminate disposed in parallel to an upper electrode in the chamber, the gas is converted into plasma. In the plasma, charge particles such as positive or negative ions or electrons, and neutral active species exist. When these etching species are adsorbed onto the lower organic layer, a chemical reaction occurs and the reaction product is eliminated from the surface and then discharged, and thus etching proceeds.

Examples of the etching gas include oxygen gas and sulfur dioxide gas. Among these etching gasses, oxygen gas is preferably used.

### (Ionic Etching Process of Magnetic Film 22′)

Using the pattern 25 thus obtained, a lead portion of a magnetic head is produced.

When ionic etching is conducted using the pattern 25 having a tapered shape including the resist patter 24 and the base pattern 23 shown in FIG. 6B as a mast, the magnetic film 22′ around the pattern 25 is etched, and thus the magnetic film 22′ at the lower portion of the pattern 25 remains and a magnetic film pattern 22 is printed as shown in FIG. 6C.

Examples of the ionic etching include anisotropic etching such as ion milling. A conventionally known method can be applied to the ion milling. For example, ion milling can be conducted by using an ion beam milling apparatus IML series, manufactured by Hitachi, Ltd.

### (Sputtering Process of the Fourth Aspect)

Subsequently, when sputtering is conducted, an electrode film 26 is formed on the pattern 25, and also formed on the substrate 21 around the magnetic film pattern 22 as shown in FIG. 6D.

Conventionally known methods can be applied to the sputtering. For example, sputtering can be conducted by using a sputtering apparatus ISM-2200 or ISP-1801, manufactured by Hitachi, Ltd.

### (Lift-Off Process of the Fourth Aspect)

Finally, when the base pattern 23 is etched by dry etching to remove (lift-off) the pattern 25, a lead portion 20 of a magnetic head which includes the substrate 21, the magnetic film pattern 22 formed on the substrate, and the electrode films 26 formed around the magnetic film pattern 22 is produced as shown in FIG. 6E.

Next, a manufacturing process of a write part (head portion for writing) of a magnetic head of a magnetic recording medium is explained using FIGS. 7A to 7C. In this process, a method is used, wherein a trench shaped fine resist pattern is formed and this resist pattern is used as a frame to form a fine magnetic film pattern by conducting plating.

FIGS. 7A to 7C are schematic views (sectional side view) showing each process of manufacturing a write part of a magnetic head.

As shown in FIG. 7A, a plating seed layer 211 is formed on a base material (illustration is omitted) wherein a desired laminate structure is formed on a substrate, and then a slit-like resist pattern 212, which has an almost rectangle-like cross-section, is formed on the plating seed layer by conducting the conventional lithography described above.

Then, as shown in FIG. 7B, a trench part (concave portion) surrounded by the formed resist pattern 212 is plated to form the magnetic film 213′.

Then, as shown in FIG. 7C, the magnetic film pattern 213 having an almost rectangle cress-section or a trapezoid cross-section (inverse tapered shape) wherein the width thereof becomes narrower toward the substrate is obtained by removing a resist pattern 212.

Although the process for manufacturing a magnetic head wherein a magnetic film 22 is provided on the substrate 21 is explained, the fourth aspect of the present invention is not restricted thereto. The negative resist composition of the third aspect of the present invention can be suitably used for all of the uses for manufacturing MEMS. Examples thereof include the use for manufacturing MRAM and the like, and the use for a case wherein a magnetic film is not provided or the like.

As described above, according to the negative resist composition of the third aspect of the present invention and the resist pattern forming method of the fourth aspect of the present invention, a resist pattern excellent in plating resistance can be formed. Therefore, the negative resist composition of the third aspect of the present invention and the resist pattern forming method of the fourth aspect of the present invention are suitable to manufacture MEMS.

Moreover, the negative resist composition of the third aspect of the present invention is excellent in sensitivity to electron rays, and therefore, can be used preferably for manufacturing MEMS wherein electron rays are used.

Furthermore, since a resin which includes a novolak resin as a basic material is used as the component (A) in the negative resist composition of the third aspect of the present invention, the rosin composition is excellent in dry etching resistance, in plant resistance, ionic etching resistance, adhesion to a substrate and heat resistance. From these viewpoints, the negative resist composition of the third aspect of the present invention and the resist pattern forming method of the fourth aspect of the present invention are suitable to manufacture MEMS.

### EXAMPLES

Hereinafter, the first and second aspects of the present invention are explained in detail but the present invention is not restricted only to the following examples.

### Examples 1 and 2 and Comparative Examples 1 and 2

Negative resist composition solutions were prepared by mixing and dissolving each component shown in Table 1.

In Table 1, the number in the parenthesis represents the mixed amount (parts by mass), The abbreviation shown in Table 1 means those described below.
(A)-2: Polyhydroxystyrene having a molecular weight of 2500 (trade name: VPS-2520, manufactured by Nippon Soda Co., Ltd.)
(A)-4: Novolak resin having a molecular weight of 4000, which is synthesized by the conventional method using m-cresol and mixed aldehydes prepared by formaldehyde/salicylaldehyde=1/0.3 (molar ratio)
(B)-1: Compound represented by the general formula (V)
(B)-2: Triphenylsulfonium nonafluorobutane sulfonate
(C)-1: Melamine-based crosslinking agent (trade name: MW100 LM, manufactured by Sanwa Chemical Co., Ltd.)

### (D)-1: Tri-n-decylamine

### (D)-3: Tri-n-pentylamine

(E)-1: Salicylic acid
Add2: Surface active agent (trade name: XR-104, manufactured by Dainippon Ink and Chemicals, Inc.)
Add3: Dye (trade name: IMP, manufactured by Daito Chemix Corporation)

### (S)-2: PGMEA

TABLE 1

| | Component | Component | Component | Component | Component | | | Organic |
|---|---|---|---|---|---|---|---|---|
| | (A) | (B) | (C) | (D) | (B) | Others | | Solvent |
| Ex. 1 | (A)-2 | (B)-1 | (C)-1 | (D)-2 | (E)-1 | Add2 | Add3 | (S)-2 |
| | (100) | (4.0) | (15) | (0.4) | (0.11) | (0.12) | (2.0) | (560) |
| Ex. 2 | (A)-4 | (B)-1 | (C)-1 | (D)-3 | (E)-1 | Add2 | — | (S)-2 |
| | (100) | (4.0) | (15) | (0.1) | (0.05) | (0.1) | | (560) |
| Com. | (A)-2 | (B)-2 | (C)-1 | (D)-2 | (E)-1 | Add2 | Add3 | (S)-2 |
| Ex. 1 | (100) | (4.0) | (15) | (0.4) | (0.11) | (0.12) | (2.0) | (560) |
| Com. | (A)-4 | (B)-2 | (C)-1 | (D)-3 | (E)-1 | Add2 | — | (S)-2 |
| Ex. 2 | (100) | (4.0) | (15) | (0.1) | (0.05) | (0.1) | | (560) |

Subsequently, the following evaluation was performed for the obtained negative resist compositions.

### (Sensitivity to Electron Rays)

Each negative resist composition solution obtained was applied uniformly to the surface of an 8-inch silicon substrate that had been treated with hexamethyldisilazane, and was then subjected to a bake treatment (PAB) at 130° C. for 90 seconds, and a resist film having the film thickness of 500 nm was formed.

This resist film was exposed with an electron beam lithography apparatus (HL-800D, manufactured by Hitachi, Ltd.) at an accelerating voltage of 70 kV, and then subjected to a bake treatment (PEB) at 110° C. for 90 seconds. Subsequently, the film was developed for 60 seconds in a 2.38% by mass TMAH aqueous solution at 23° C.

Then, whether a pattern was formed on the obtained substrates was observed with a scanning electron microscope (SEM).

As the result, it turned out that the pattern was formed in the films of Example 1 and Comparative Example 1, and therefore the compositions had sensitivity to electron rays.

Moreover, in the evaluation of the sensitivity regarding electron rays, the critical resolution (nm) at the optimal exposure (Eop) at which a trench pattern having a width of 80 nm was formed was determined. The results are shown in Table 2 as “resolution”.

TABLE 2

| | Resolution |
|---|---|
| Example 1 | 60 nm |
| Example 2 | 70 nm |
| Comparative Example 1 | 60 nm |
| Comparative Example 2 | 70 nm |

### (Sensitivity to KrF Excimer Lasers)

Similar to the aforementioned method, a resist film having a film thickness of 500 nm was formed, and this film was exposed selectively to KrF excimer lasers (248 nm) through a mask pattern using a KrF exposure equipment FPA3000EX3 (manufactured by Canon Inc., NA (numerical aperture)=0.55, σ=0.55). Then, the exposed resist film was subjected to bake treatment (PEB) at 110° C. for 90 seconds, and subsequently subjected to development for 60 seconds at 23° C. in a 2.38% by mass aqueous solution of tetramethylammonium hydroxide. Whether a pattern was formed on the substrate was observed with SEM, and it was found that the pattern was formed on the films of Example 1 and Comparative Example 1, and therefore they had sensitivity to KrF excimer lasers.

### (Sensitivity to G-Rays)

Similar to the aforementioned method, a resist film having a film thickness of 500 nm was formed, and this film was exposed selectively to g-rays (436 nm) through a mask pattern using NSR-1505G7E (manufactured by Nikon Corporation). Then, the exposed resist film was subjected to bake treatment (PER) at 110° C. for 90 seconds, and subsequently subjected to development for 60 seconds at 23° C. in a 2.38% by mass aqueous solution of tetramethylammonium hydroxide. As the result, it was found that a patter was formed on the film of Example 1, and therefore the composition of Example 1 had sensitivity to g-rays. On the other hand, it was found that a pattern was not formed on the film of Comparative Examples 1 and 2, and therefore the compositions thereof did not have sensitivity to g-rays.

### (Sensitivity to I-Rays)

Similar to the aforementioned method, a resist film having a film thickness of 500 nm was formed, and this film was exposed selectively to i-rays (365 nm) through a mask pattern using NSR-2205i14E (manufactured by Nikou Corporation). Then, the exposed resist film was subjected to bake treatment (PEB) at 110° C. for 90 seconds, and subsequently subjected to development for 60 seconds at 23° C. in a 2.38% by mass aqueous solution of tetramethylammonium hydroxide.

As the result, it was found that a pattern was formed on the film of Example 1, and therefore the composition of Example 1 had sensitivity to i-rays. On the other hand, it was found that a pattern was not formed on the films of Comparative Examples 1 and 2 and therefore the compositions thereof did not have sensitivity to i-rays.

As is apparent from the results shown above, the negative resist compositions of Examples 1 and 2 have sensitivity to all of the exposure light sources of g-rays, i-rays, KrF excimer lasers and electron rays, and therefore “mix and match” can be performed by selecting and using two or more light sources form the light sources optionally. Moreover, the resist pattern having high resolution can be formed.

On the other hand, the negative resist compositions of Comparative Examples 1 and 2 wherein only (B)-2 was included as the component (B) had sensitivity to KrF excimer lasers and electron rays, and the pattern with high resolution was formed using electron rays. However, they did not have sensitivity to g-rays and i-rays. Accordingly, it is clear that “mix and match” cannot be performed by selecting and using at least two of g-rays, i-rays, KrF excimer lasers and electron rays optionally.

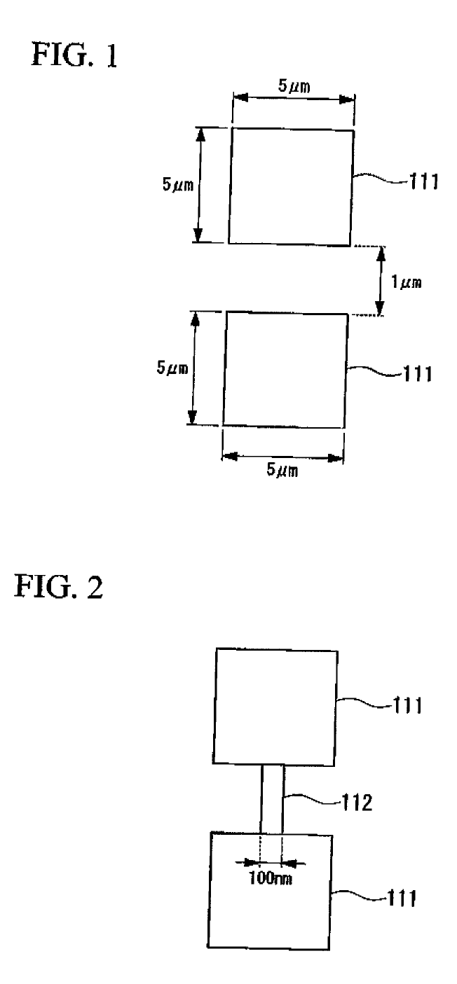

Next, the “mix and match” was actually performed. That is, a resist pattern was formed using the negative resist composition of Example 1 by the “mix and match” method using i-rays and electron rays according to the procedure shown in FIGS. 1 to 3. The conditions for exposure of i-rays and electron rays were the same as those used in the aforementioned evaluation. Here, scales of FIGS. 1 to 3 are partially changed from actual sizes for the convenience of explanation.

First, a magnetic film was formed on the substrate, and a base film was furthermore laminated thereon to form a laminate. Then, a resist film was formed on the laminate similar to the aforementioned method. Said base film was formed using TBLC-100 manufactured by Tokyo Osaka Kogyo Co., Ltd.

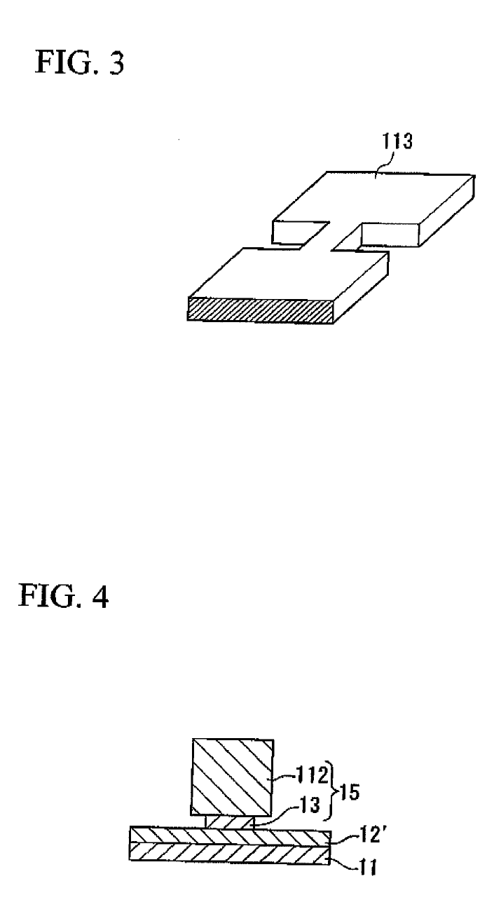

Subsequently, as shown in FIG. 1, large area patterns 111 and 111, which were 5 μm square, were formed at the interval of 1 μm using i-rays. Then, as shown in FIG. 2, a line pattern 112 having a width of 100 nm was formed using the electron rays so that the aforementioned patterns 111 and 111 were connected. In this way, a resist pattern 113 wherein the large area patterns 111 and 111 were connected by the line pattern 112 was formed. The perspective view of the resist pattern 113 is shown in FIG. 3.

At this time, the base film located under the portion from which the resist film was removed was removed by carrying out over-etching, and the base pattern 3 was formed. The longitudinal sectional view at the portion of the line pattern 112 is shown in FIG. 4.

As show in FIG. 4, a paddle-shaped pattern 15 including the base pattern 13 and the line pattern 112 was formed on the magnetic film 12′ laminated on the substrate 11.

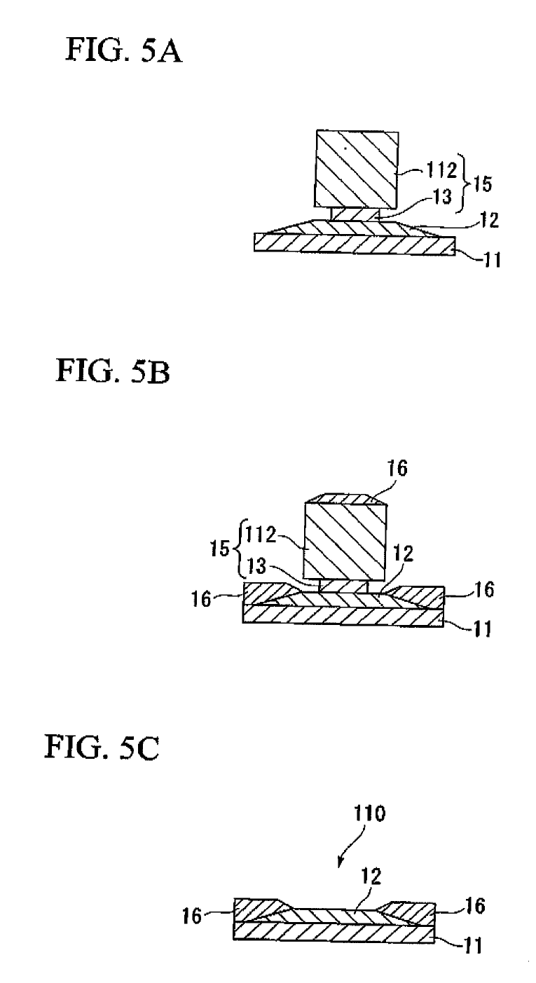

Subsequently, a lead part of a magnetic head was formed according to the procedure shown in FIGS. 5A to 5C using a pattern 15.

When ion milling using the ion beam milling equipment (IML series, manufactured by Hitachi, Ltd.) was performed by using the pattern 15 as a mask, the magnetic film 12′ at the position surrounding the pattern 15 was etched as shown in FIG. 5A, and the magnetic film 12′ under the pattern 15 remained and the magnetic film pattern 12 was printed.

When sputtering using the sputtering equipment ISM-2200 manufactured by Hitachi, Ltd. was further performed, the electrode 16 was formed on both of the pattern 15 and the substrate 11 around the magnetic film pattern 12 as shown in FIG. 5B.

Finally, by etching the base pattern 3 by conducting dry etching to remove the pattern 15 (lift-off), a lead part 110 of the magnetic head including the substrate 11, the magnetic film pattern 12 formed on the substrate and the electrode film 16 formed around the pattern were manufactured as shown in FIG. 5C.

Hereinafter the third and fourth aspects of the present invention are explained in detail, but the present invention is not restricted to the following examples.

### Example 3 and Reference Example 1

Negative resist composition solutions were prepared by mixing and dissolving each component shown in Table 3.

In Table 3, the number in the parenthesis represents the mixed amount (parts by mass). Moreover, the abbreviation shown in Table 3 means those described below.

(A)-4: Novolak resin having a molecular weight of 4000, which is synthesized by the conventional method using m-cresol and mixed aldehydes prepared from formaldehyde/salicylaldehye=1/0.3 (molar ratio)
(A)-2; Polyhydroxystyrene having a molecular weight of 2500 (trade name: VPS-2520, manufactured by Nippon Soda Co., Ltd.)
(B)-1: Compound represented by the general formula (V) described above
(C)-1: Melamine-based crosslinking agent (trade name: MW100 LM, manufactured by Sanwa Chemical Co., Ltd.)

### (D)-3: Tri-n-pentylamine

(E)-1: Salicylic acid
Add2: Surface active agent (trade name: XR-104, manufactured by Dainippon Ink and Chemicals, Inc.)

### (S)-2: PGMEA

TABLE 3

| | Component | Component | Component | Component | Component | | Organic |
|---|---|---|---|---|---|---|---|
| | (A) | (B) | (C) | (D) | (E) | Others | Solvent |
| Example 3 | (A)-4 | (B)-1 | (C)-1 | (D)-3 | (E)-1 | Add2 | (S)-2 |
| | (100) | (4.0) | (15) | (0.1) | (0.05) | (0.1) | (560) |
| Reference | (A)-2 | (B)-1 | (C)-1 | (D)-3 | (E)-1 | Add2 | (S)-2 |
| Example 1 | (100) | (4.0) | (15) | (0.1) | (0.05) | (0.1) | (560) |

Subsequently, the following evaluation was performed for the obtained negative resist composition of the third aspect of the present invention.

The negative resist composition solution was applied uniformly to the surface of an 8-inch silicon substrate that had been treated with hexamethyldisilazane, and was then subjected to a bake treatment (PAB) at 130° C. for 90 seconds, thus forming a resist film having the film thickness of 500 nm.

This resist film was then exposed with an electron beam lithography apparatus (HL-800D, manufactured by Hitachi, Ltd.) at an accelerating voltage of 70 kV, and was subsequently subjected to a bake treatment (PEB) at 110° C. for 90 seconds, and developed for 60 seconds in a 2.38% by mass TMAH aqueous solution at 23° C. Then, the substrate was rinsed in pure water for 30 seconds, and dried by straining off water, and then, post baking treatment was conducted for 60 seconds at the temperature of 100° C. to form a resist pattern (trench pattern having the width of 200 nm).

Then, plating treatment was performed on the substrate, wherein the pattern was formed at the temperature of 65° C. for 40 minutes by the electrolytic plating method using a non-cyanogen type gold sulfite plating solution.

Subsequently, the gold plating state was observed using the optical microscope or the electron microscope. Evaluation was conducted such that it was evaluated as “◯” (good) when no peeling of gold plating was observed, and it was evaluated as “x” (poor) when peeling of gold plating was observed. These results are shown as the plating resistance in Table 4.

TABLE 4

| | Plating resistance |
|---|---|
| Example 3 | ∘ |
| Reference Example 1 | x |

From the results shown in Table 4, it was found that Example 3 wherein the novolak resin (A)-4 was used as the component (A) had sensitivity to electron rays. Furthermore, the degree of resolution thereof was the same as or superior to those of Reference Example 1, and plating resistance of Example 3 was excellent.

On the other hand, Reference Example 1 wherein polyhydroxystyrene (A)-2 was used instead of the resin (A)-4 had sensitivity similar to that of Example 3, but inferior to plating resistance.

### INDUSTRIAL APPLICABILITY

According to the present invention, the negative resist composition can be provided wherein the composition has the sensitivity to g-rays, i-rays, KrF excimer lasers and electron rays, and can be used for an exposing process wherein exposure is conducted using at least two exposure light sources selected from g-rays, i-rays, KrF excimer lasers and electron rays, and can form resist pattern having excellent high resolution, and can be used for manufacturing MEMS. The resist pattern forming method using the composition be also provided. Due to the use of the negative resist composition and the resist pattern forming method of the present invention, it is possible to perform “mix and match” by using any of g-rays, i-rays, KrF excimer lasers and electron rays, and is possible to form a resist pattern having high resolution and excellent plating resistance, and therefore it is possible to manufacture MEMS using the resist composition and the method.

What is claimed is:

1. A negative resist composition used for a process in which at least two exposure light sources selected from g-rays, i-rays, KrF excimer lasers and electron rays are used; wherein
the negative resist composition comprises an alkali-soluble resin component (A), an acid generator component (B), which generates acid due to exposure to g-rays, i-rays, KrF excimer lasers and electron rays, and a crosslinking agent (C).

2. The negative resist composition according to claim 1, wherein the alkali-soluble resin component (A) is an alkali-soluble novolak resin.

3. The negative resist composition according to claim 1, wherein the alkali-soluble resin component (A) is a resin comprising a structural unit derived from hydroxystyrene.

4. The negative resist composition according to claim 1, wherein the acid generator component (B) is an oximesulfonate-based acid generator.

5. The negative resist composition according to claim 1, wherein the resist composition further comprises a nitrogen-containing organic compound (D).

6. A resist pattern forming method which comprises:
forming a resist film on a substrate using the negative resist composition of claim 1;
exposing the resist film selectively using at least two of exposure light sources selected from g-rays, i-rays, KrF excimer lasers and electron rays; and
performing alkali development of the exposed resist film to form a resist pattern.

7. A negative resist composition for manufacturing micro electro mechanical systems, which comprises an alkali-soluble novolak resin (A), an acid generator component (B) which generates an acid due to the exposure of radiation and a crosslinking agent component (C).

8. The negative resist composition according to claim 7, wherein the acid generator component (B) is an oximesulfonate-based acid generator.

9. The negative resist composition according to claim 7, wherein the resist composition further comprises a nitrogen-containing organic compound (D).

10. A resist pattern forming method which comprises: forming a resist film on a substrate using the negative resist composition according to claim 7, exposing the resist film selectively, and performing alkali development of the exposed resist to form a resist pattern.
